(19) United States
(12) Patent Application Publication
(10) Pub. No.: US 2026/0049388 A1
(43) Pub. Date: Feb. 19, 2026

(54) DEPOSITION MASK, DEPOSITION APPARATUS INCLUDING THE SAME, METHOD OF MANUFACTURING THE SAME, AND ELECTRONIC DEVICE MANUFACTURED BY USING THE SAME

(71) Applicant: Samsung Display Co., LTD., Yongin-si (KR)

(72) Inventor: Duck Jung LEE, Yongin-si (KR)

(21) Appl. No.: 19/171,736

(22) Filed: Apr. 7, 2025

(30) Foreign Application Priority Data
Aug. 16, 2024 (KR) 10-2024-0109589

(51) Int. Cl. C23C 14/04; C23C 14/00; H10K 59/12; H10K 71/16

(52) U.S. Cl. CPC C23C 14/042; H10K 59/1201; H10K 71/166; C23C 14/0021

(57) ABSTRACT

A deposition mask includes a mask frame having a cell opening, and a membrane disposed on the mask frame and having a plurality of pixel openings connected to the cell opening. The membrane includes a rib region defining the pixel openings. At least one heterogeneous material pattern made of a material different from the membrane is disposed on the rib region or at least one groove is formed in the rib region.

This application claims priority to Korean Patent Application No. 10-2024-0109589, filed on Aug. 16, 2024, and all the benefits accruing therefrom under 35 U.S. C. § 119, the content of which in its entirety is herein incorporated by reference.

### BACKGROUND

### 1. Technical Field

The invention relates generally to a deposition mask, and more particularly to a deposition mask, a deposition apparatus including the same, a method of manufacturing the same, and an electronic device manufactured by using the same.

### 2. Description of the Related Art

Wearable devices in which a focus is formed at a distance close to a user's eyes have been developed in the form of glasses or a helmet. For example, the wearable device may be a head mounted display (HMD) device or AR glasses. The wearable device may provide an augmented reality (hereinafter, referred to as “AR”) screen or a virtual reality (hereinafter, referred to as “VR”) screen to the user.

In the case of wearable devices, such as the HMD device or the AR glasses, a display specification of approximately 3000 PPI (pixels per inch) or higher is required to allow users to use them for a long time without symptoms of dizziness. To this end, organic light emitting diode on silicon (OLEDoS) technology used in high-resolution small-sized organic light emitting display devices is emerging. The OLEDoS is a technology in which organic light emitting diodes (OLEDs) are disposed on a semiconductor substrate on which complementary metal oxide semiconductor (CMOS) elements are disposed.

In order to manufacture a display panel with a high resolution of about 3000 PPI or higher, a high-resolution deposition mask is required. For example, the deposition mask may be manufactured by forming a membrane having a plurality of pixel openings on a substrate such as a silicon wafer, and partially etching the substrate to form cell openings that expose the pixel openings. However, deformation of the membrane may occur during the manufacturing of the deposition mask. For example, the gap between the pixel openings may be increased or decreased, resulting in degradation of the pixel position accuracy (PPA) of the pixel openings.

### SUMMARY

Aspects and features of the invention provide a deposition mask capable of improving the PPA of pixel openings, a deposition apparatus including the same, a method for manufacturing the same, and an electronic device manufactured by using the same.

However, the invention is not limited to those set forth herein. The above and other embodiments of the invention will become more apparent to one of ordinary skill in the art to which the invention pertains by referencing the detailed description given below.

According to one or more embodiments, a deposition mask may include a mask frame having a cell opening, and a membrane disposed on the mask frame and having a plurality of pixel openings connected to the cell opening. The membrane may include a rib region defining the pixel openings. At least one heterogeneous material pattern made of a material different from the membrane may be disposed on the rib region or at least one groove may be formed in the rib region.

In an embodiment, the heterogeneous material pattern may extend in a direction that is perpendicular to a direction of a gap between neighboring pixel openings.

In an embodiment, the heterogeneous material pattern may have a higher coefficient of thermal expansion than the membrane.

In an embodiment, the heterogeneous material pattern may include metal.

In an embodiment, the heterogeneous material pattern may include tungsten (W), molybdenum (Mo), zirconium (Zr), hafnium (Hf), chromium (Cr), tantalum (Ta), titanium (Ti), platinum (Pt), yttrium (Y), palladium (Pd), nickel (Ni), cobalt (Co), gold (Au), copper (Cu), silver (Ag), tin (Sn), aluminum (Al), or zinc (Zn).

In an embodiment, the groove may extend in a direction that is perpendicular to a direction of a gap between neighboring pixel openings.

In an embodiment, the groove may have a depth of about 0.1 to about 0.7 times a thickness of the membrane.

In an embodiment, the deposition mask may further include at least one spacer disposed on the membrane, wherein the at least one spacer may have the same thickness as the heterogeneous material pattern.

In an embodiment, the spacer may be made of the same material as the membrane or the heterogeneous material pattern.

According to one or more embodiments, a deposition apparatus may include a deposition source, a deposition mask disposed above the deposition source, and a substrate chuck disposed above the deposition mask and supporting the substrate such that the substrate faces the deposition mask. The deposition mask may include a mask frame having a cell opening, and a membrane disposed on the mask frame and having a plurality of pixel openings connected to the cell opening. The membrane may include a rib region defining the pixel openings. At least one heterogeneous material pattern made of a material different from the membrane may be disposed on the rib region or at least one groove may be formed between the pixel openings.

According to one or more embodiments, a method of manufacturing a deposition mask may include forming a membrane on a substrate, patterning the membrane to form a plurality of pixel openings exposing the substrate, patterning the substrate to form a cell opening connected to the pixel openings, measuring a gap between the pixel openings, detecting a first portion where the gap between the pixel openings is wider than a predetermined gap, or a second portion where the gap between the pixel openings is narrower than the predetermined gap, forming at least one heterogeneous material pattern made of a material different from the membrane on the first portion when the first portion is detected, and forming at least one groove in the second portion when the second portion is detected.

In an embodiment, the heterogeneous material pattern may extend in a direction that is perpendicular to a direction of a gap between pixel openings disposed on both sides of the first portion.

In an embodiment, the heterogeneous material pattern may have a higher coefficient of thermal expansion than the membrane.

In an embodiment, the heterogeneous material pattern may include metal.

In an embodiment, the heterogeneous material pattern may include tungsten (W), molybdenum (Mo), zirconium (Zr), hafnium (Hf), chromium (Cr), tantalum (Ta), titanium (Ti), platinum (Pt), yttrium (Y), palladium (Pd), nickel (Ni), cobalt (Co), gold (Au), copper (Cu), silver (Ag), tin (Sn), aluminum (Al), or zinc (Zn).

In an embodiment, the heterogeneous material pattern may be formed through a laser chemical vapor deposition process.

In an embodiment, the forming of the heterogeneous material pattern may include providing a source gas comprising the metal onto the first portion, and irradiating a laser beam onto the first portion to form the heterogeneous material pattern.

In an embodiment, the groove may extend in a direction that is perpendicular to a direction of a gap between pixel openings disposed on both sides of the second portion.

In an embodiment, the groove may have a depth of about 0.1 to about 0.7 times a thickness of the membrane.

In an embodiment, the groove may be formed through a laser ablation process.

In an embodiment, the method may further include forming at least one spacer on the membrane.

In an embodiment, the spacer may have the same thickness as the heterogeneous material pattern.

In an embodiment, the spacer may be made of the same material as the membrane or the heterogeneous material pattern.

According to one or more embodiments, an electronic device may include a display panel, where the display panel may include a backplane substrate and light-emitting layers formed on the backplane substrate by using a deposition mask. The deposition mask may include a mask frame having a cell opening, and a membrane disposed on the mask frame and having a plurality of pixel openings connected to the cell opening. The membrane may include a rib region defining the pixel openings. At least one heterogeneous material pattern made of a material different from the membrane may be disposed on the rib region or at least one groove may be formed in the rib region.

According to embodiments as stated above, when the gap between the pixel openings is wide or narrow, the gap between the pixel openings may be compensated by a heterogeneous material pattern or a groove, so that the gap between the pixel openings may be made uniform and the PPA of the deposition mask may be improved.

Other features and embodiments may be apparent from the following detailed description and the drawings.

### BRIEF DESCRIPTION OF THE DRAWINGS

The above and other aspects and features of the invention will become more apparent by describing in detail exemplary embodiments thereof with reference to the attached drawings, in which:

FIG. 1 is an exploded perspective view illustrating a display device, according to an embodiment;

FIG. 2 is a block diagram for explaining the display device shown in FIG. 1, according to an embodiment;

FIG. 3 is an equivalent circuit diagram for explaining an example of a first sub-pixel shown in FIG. 2, according to an embodiment;

FIG. 4 is a schematic plan view illustrating an example of the display panel shown in FIG. 1, according to an embodiment;

FIG. 5 is a schematic plan view illustrating an example of the display area shown in FIG. 4, according to an embodiment;

FIG. 6 is a schematic plan view illustrating another example of the display area shown in FIG. 4, according to an embodiment;

FIG. 7 is a cross-sectional view illustrating an example of the display panel taken along line I-I′ of FIG. 5, according to an embodiment;

FIG. 8 is a schematic perspective view illustrating an example of a head mounted display, according to an embodiment;

FIG. 9 is a schematic exploded perspective view illustrating the head mounted display shown in FIG. 8, according to an embodiment;

FIG. 10 is a schematic perspective view illustrating another example of a head mounted display, according to an embodiment;

FIG. 11 is a schematic view illustrating a deposition mask and a deposition apparatus including the same, according to an embodiment;

FIG. 12 is a schematic bottom view illustrating a backplane substrate as shown in FIG. 11, according to an embodiment;

FIG. 13 is a schematic plan view illustrating a deposition mask as shown in FIG. 11, according to an embodiment;

FIG. 14 is a schematic enlarged plan view illustrating mask cell regions as shown in FIG. 13, according to an embodiment;

FIG. 15 is a schematic cross-sectional view taken along line II-II′ as shown in FIG. 14, according to an embodiment;

FIG. 16 is a schematic enlarged plan view illustrating a heterogeneous material pattern as shown in FIG. 15;

FIG. 17 is a schematic enlarged cross-sectional view illustrating the heterogeneous material pattern as shown in FIG. 15, according to an embodiment;

FIG. 18 is a cross-sectional view illustrating a deposition mask, according to another embodiment;

FIG. 19 is a schematic enlarged plan view illustrating a groove as shown in FIG. 18, according to an embodiment;

FIG. 20 is a schematic enlarged cross-sectional view illustrating the groove as shown in FIG. 18, according to an embodiment;

FIG. 21 is a schematic cross-sectional view illustrating a deposition mask, according to still another embodiment;

FIG. 22 is a schematic cross-sectional view illustrating a method of manufacturing a deposition mask, according to an embodiment;

FIG. 23 is a schematic cross-sectional view illustrating a method of manufacturing a deposition mask, according to an embodiment;

FIG. 24 is a schematic cross-sectional view illustrating a method of manufacturing a deposition mask, according to an embodiment;

FIG. 25 is a schematic cross-sectional view illustrating a method of manufacturing a deposition mask, according to an embodiment;

FIG. 26 is a schematic cross-sectional view illustrating a method of manufacturing a deposition mask, according to an embodiment;

FIG. 27 is a schematic cross-sectional view illustrating a method of manufacturing a deposition mask, according to an embodiment;

FIG. 28 is a schematic cross-sectional view illustrating a method of manufacturing a deposition mask, according to an embodiment; and

FIG. 29 is a schematic cross-sectional view illustrating a method of manufacturing a deposition mask, according to an embodiment.

### DETAILED DESCRIPTION

The invention will now be described more fully hereinafter with reference to the accompanying drawings, in which various embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Features of each of various embodiments may be partially or entirely combined with each other and may technically variously interwork with each other, and respective embodiments may be implemented independently of each other or may be implemented together in association with each other.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within about ±30%, about 20%, about 10% or about 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the invention.

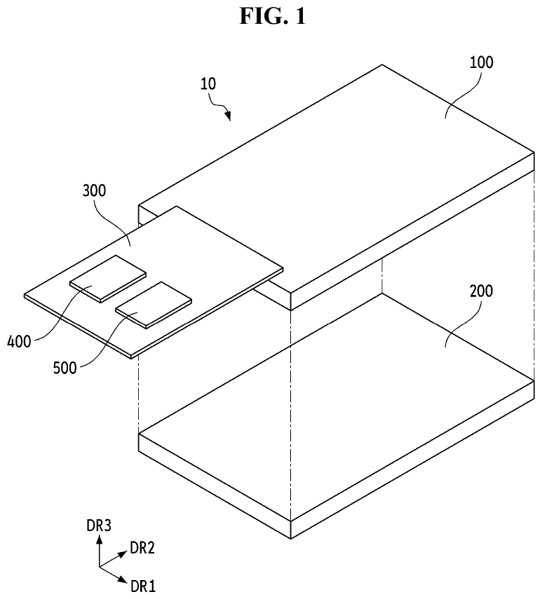

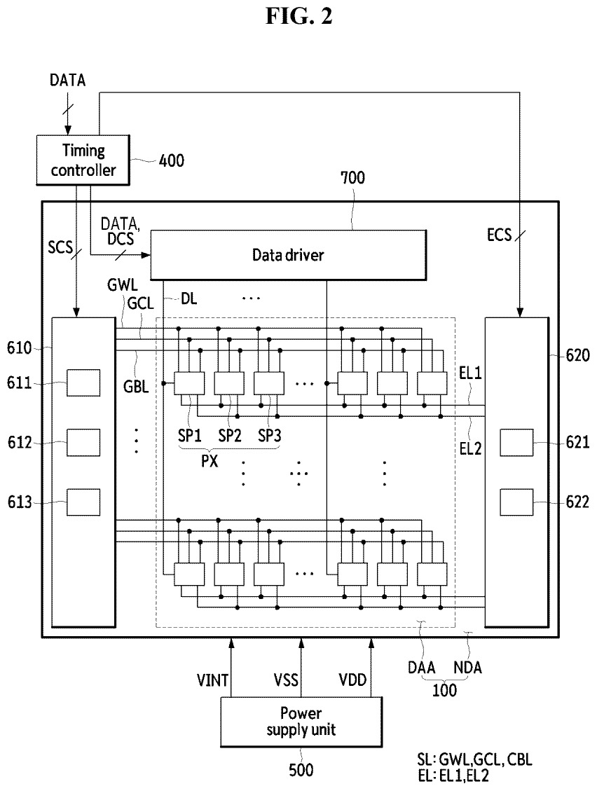

FIG. 1 is an exploded perspective view illustrating a display device, according to an embodiment. FIG. 2 is a block diagram for explaining the display device shown in FIG. 1, according to an embodiment.

In an embodiment and referring to FIGS. 1 and 2, a display device 10 may be a device displaying a moving image or a still image, where the display device 10 may be applied to portable electronic devices such as, for example, a mobile phone, a smartphone, a tablet personal computer (PC), a mobile communication terminal, an electronic organizer, an electronic book, a portable multimedia player (PMP), a navigation system, an ultra mobile PC (UMPC) or the like. For example, the display device 10 may be applied as a display unit of electronic devices such as, for example, a television, a laptop, a monitor, a billboard, an Internet-of-Things (IoT) device, and the like. In another embodiment, the display device 10 may be applied to electronic devices such as, for example, a smart watch, a watch phone, a head mounted display (HMD) for implementing virtual reality and augmented reality, and the like.

In an embodiment, the display device 10 may include a display panel 100, a heat dissipation layer 200, a circuit board 300, a timing control circuit 400, and a power supply circuit 500.

In an embodiment, the display panel 100 may have a planar shape that is similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a predetermined curvature. The planar shape of the display panel 100 is not limited to a quadrilateral shape and may be a shape similar to another polygonal shape, a circular shape, or an elliptical shape. The planar shape of the display device 10 may conform to the planar shape of the display panel 100, but the invention is not limited thereto.

In an embodiment, the display panel 100 may include a plurality of pixels PX, a plurality of scan lines SL, a plurality of emission control lines EL, a plurality of data lines DL, a scan driver 610, an emission driver 620, and a data driver 700. As shown in FIG. 2, the display panel 100 may be divided into a display area DAA displaying an image and a non-display area NDA not displaying an image.

In an embodiment, the plurality of pixels PX may be disposed in the display area DAA, where the plurality of pixels PX may be arranged in a matrix form along the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

In an embodiment, the plurality of scan lines SL may include a plurality of write scan lines GWL, a plurality of control scan lines GCL, and a plurality of bias scan lines GBL. The plurality of emission control lines EL may include a plurality of first emission control lines EL1 and a plurality of second emission control lines EL2.

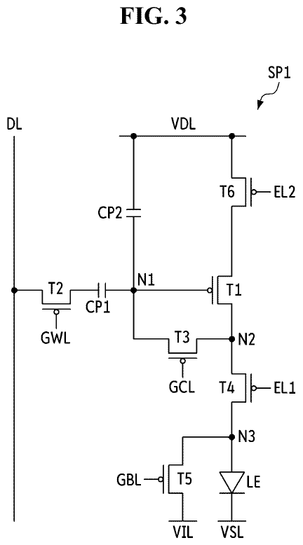

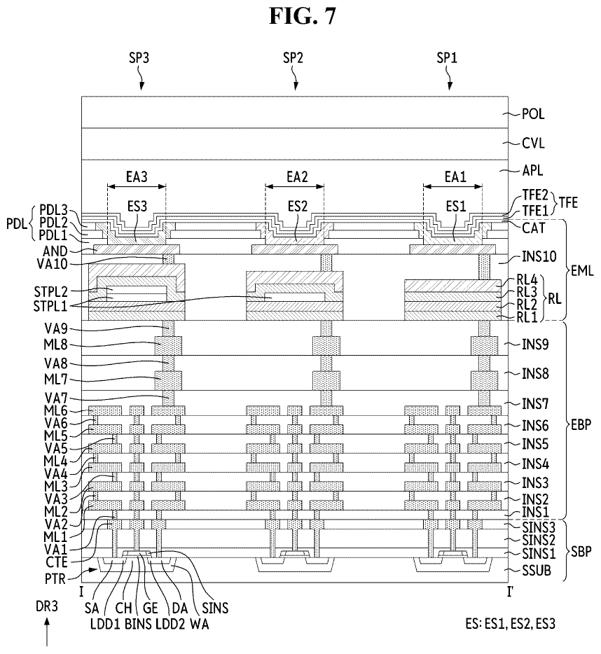

In an embodiment, the plurality of pixels PX may include a plurality of sub-pixels SP1, SP2, and SP3. The plurality of sub-pixels SP1, SP2, and SP3 may include a plurality of pixel transistors (see FIG. 3). The plurality of pixel transistors may be formed by a semiconductor process, and may be disposed on a semiconductor substrate SSUB (see FIG. 7). For example, the plurality of pixel transistors of the data driver 700 may be formed through a complementary metal oxide semiconductor (CMOS) process, but the present disclosure is not limited thereto.

In an embodiment, each of the plurality of sub-pixels SP1, SP2, and SP3 may be connected to any one write scan line GWL among the plurality of write scan lines GWL, any one control scan line GCL among the plurality of control scan lines GCL, any one bias scan line GBL among the plurality of bias scan lines GBL, any one first emission control line EL1 among the plurality of first emission control lines EL1, any one second emission control line EL2 among the plurality of second emission control lines EL2, and any one data line DL among the plurality of data lines DL. Each of the plurality of sub-pixels SP1, SP2, and SP3 may receive a data voltage of the data line DL in response to a write scan signal of the write scan line GWL, and emit light from the light-emitting element according to the data voltage.

In an embodiment, the scan driver 610, the emission driver 620, and the data driver 700 may be disposed in the non-display area NDA.

The scan driver 610 may include a plurality of scan transistors, and the emission driver 620 may include a plurality of light-emitting transistors, where the plurality of scan transistors and the plurality of light-emitting transistors may be formed on the semiconductor substrate SSUB (see FIG. 7) through a semiconductor process. For example, the plurality of scan transistors and the plurality of light-emitting transistors may be formed through a CMOS process, but the invention is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to bias scan lines GBL.

In an embodiment, the emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

In an embodiment, the data driver 700 may include a plurality of data transistors, and the plurality of data transistors may be formed through a semiconductor process and formed on the semiconductor substrate SSUB (see FIG. 7). For example, the plurality of data transistors may be formed through a CMOS process, but the invention is not limited thereto.

The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. In this case, the sub-pixels SP1, SP2, and SP3 may be selected by the write scan signal of the scan driver 610, and data voltages may be supplied to the selected sub-pixels SP1, SP2, and SP3.

In an embodiment, the heat dissipation layer 200 may overlap the display panel 100 in a third direction DR3, which is a thickness direction of the display panel 100. The heat dissipation layer 200 may be disposed on one surface of the display panel 100, for example, on the rear surface thereof. The heat dissipation layer 200 serves to dissipate heat generated from the display panel 100. The heat dissipation layer 200 may include a metal layer having high thermal conductivity, such as graphite, silver (Ag), copper (Cu), or aluminum (Al).

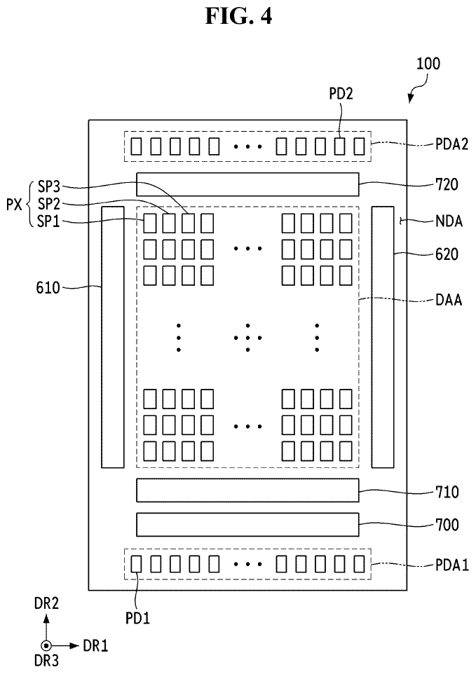

In an embodiment, the circuit board 300 may be electrically connected to a plurality of first pads PD1 (see FIG. 4) of a first pad portion PDA1 (see FIG. 4) of the display panel 100 by using a conductive adhesive member such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. In this case, one end of the circuit board 300 may be disposed on the rear surface of the display panel 100 and/or the rear surface of the heat dissipation layer 200. The other end of the circuit board 300 may be connected to the plurality of first pads PD1 (see FIG. 4) of the first pad portion PDA1 (see FIG. 4) of the display panel 100 by using a conductive adhesive member. One end of the circuit board 300 may be an opposite end of an adjacent circuit board 300.

In an embodiment, the timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

In an embodiment, the power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 3.

Each of the timing control circuit 400 and the power supply circuit 500 may be formed as an integrated circuit (IC) and attached to one surface of the circuit board 300. In this case, the scan timing control signal SCS, the emission timing control signal ECS, digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

As another embodiment, each of the timing control circuit 400 and the power supply circuit 500 may be disposed in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed through a semiconductor process and formed on the semiconductor substrate SSUB (see FIG. 7). For example, the plurality of timing transistors and the plurality of power transistors may be formed through a CMOS process, but the invention is not limited thereto. Each of the timing control circuit 400 and the power supply circuit 500 may be disposed between the data driver 700 and the first pad portion PDA1 (see FIG. 4).

FIG. 3 is an equivalent circuit diagram for explaining an example of a first sub-pixel shown in FIG. 2, according to an embodiment.

In an embodiment and referring to FIG. 3, the first sub-pixel SP1 may be connected to the write scan line GWL, the control scan line GCL, the bias scan line GBL, the first emission control line EL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be lower than the third driving voltage VINT. The second driving voltage VDD may be higher than the third driving voltage VINT.

In an embodiment, the first sub-pixel SP1 may include a plurality of transistors T1 to T6, a light-emitting element LE, a first capacitor CP1, and a second capacitor CP2.

In an embodiment, the light-emitting element LE emits light in response to a driving current flowing through the channel of the first transistor T1. The emission amount of the light-emitting element LE may be proportional to the driving current. The light-emitting element LE may be disposed between a fourth transistor T4 and the first driving voltage line VSL. The first electrode of the light-emitting element LE may be connected to the drain electrode of the fourth transistor T4, and the second electrode thereof may be connected to the first driving voltage line VSL. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer disposed between the first electrode and the second electrode, but the present disclosure is not limited thereto. For example, the light-emitting element LE may be an inorganic light-emitting element including a first electrode, a second electrode, and an inorganic semiconductor disposed between the first electrode and the second electrode, in which case the light-emitting element LE may be a micro light-emitting diode.

In an embodiment, the first transistor T1 may be a driving transistor that controls a source-drain current (hereinafter referred to as “driving current”) flowing between the source electrode and the drain electrode thereof according to a voltage applied to the gate electrode thereof. The first transistor T1 may include a gate electrode connected to a first node N1, a source electrode connected to the drain electrode of a sixth transistor T6, and a drain electrode connected to a second node N2.

In an embodiment, a second transistor T2 may be disposed between one electrode of the first capacitor CP1 and the data line DL. The second transistor T2 may be turned on by the write scan signal of the write scan line GWL to connect the one electrode of the first capacitor CP1 to the data line DL. Accordingly, the data voltage of the data line DL may be applied to the one electrode of the first capacitor CP1. The second transistor T2 may include a gate electrode connected to the write scan line GWL, a source electrode connected to the data line DL, and a drain electrode connected to the one electrode of the first capacitor CP1.

In an embodiment, a third transistor T3 may be disposed between the first node N1 and the second node N2. The third transistor T3 is turned on by the control scan signal of the control scan line GCL to connect the first node N1 to the second node N2. For this reason, when the gate electrode and the source electrode of the first transistor T1 are connected, the first transistor T1 may operate like a diode. The third transistor T3 may include a gate electrode connected to the control scan line GCL, a source electrode connected to the second node N2, and a drain electrode connected to the first node N1.

In an embodiment, the fourth transistor T4 may be connected between the second node N2 and a third node N3. The fourth transistor T4 is turned on by the first emission control signal of the first emission control line EL1 to connect the second node N2 to the third node N3. Accordingly, the driving current of the first transistor T1 may be supplied to the light-emitting element LE. The fourth transistor T4 may include a gate electrode connected to the first emission control line EL1, a source electrode connected to the second node N2, and a drain electrode connected to the third node N3.

In an embodiment, a fifth transistor T5 may be disposed between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light-emitting element LE. The fifth transistor T5 may include a gate electrode connected to the bias scan line GBL, a source electrode connected to the third node N3, and a drain electrode connected to the third driving voltage line VIL.

In an embodiment, the sixth transistor T6 may be disposed between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and a drain electrode connected to the source electrode of the first transistor T1.

In an embodiment, the first capacitor CP1 may be disposed between the first node N1 and the drain electrode of the second transistor T2. The first capacitor CP1 may include one electrode connected to the drain electrode of the second transistor T2 and the other electrode connected to the first node N1.

In an embodiment, the second capacitor CP2 is formed between the gate electrode of the first transistor T1 and the second driving voltage line VDL. The second capacitor CP2 may include one electrode connected to the gate electrode of the first transistor T1 and the other electrode connected to the second driving voltage line VDL.

In an embodiment, the first node N1 is a junction between the gate electrode of the first transistor T1, the drain electrode of the third transistor T3, the other electrode of the first capacitor CP1, and the one electrode of the second capacitor CP2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light-emitting element LE.

In an embodiment, each of the transistors T1 to T6 may be a metal-oxide-semiconductor field effect transistor (MOSFET). For example, each of the transistors T1 to T6 may be a P-type MOSFET, but the invention is not limited thereto. Each of the transistors T1 to T6 may be an N-type MOSFET. In another embodiment, some of the transistors T1 to T6 may be P-type MOSFETs, and each of the remaining transistors may be an N-type MOSFET.

Although it is illustrated in FIG. 3 that the first sub-pixel SP1 includes six transistors T1 to T6 and two capacitors C1 and C2, it should be noted that the equivalent circuit diagram of the first sub-pixel SP1 is not limited to that shown in FIG. 3. For example, the number of transistors and the number of capacitors of the first sub-pixel SP1 are not limited to those shown in FIG. 3.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 will be omitted in the present disclosure.

FIG. 4 is a schematic plan view illustrating an example of the display panel shown in FIG. 1, according to an embodiment.

In an embodiment and referring to FIG. 4, the display area DAA of the display panel 100 may include the plurality of pixels PX arranged in a matrix form. The non-display area NDA of the display panel 100 may include the scan driver 610, the emission driver 620, the data driver 700, a first distribution circuit 710, a second distribution circuit 720, the first pad portion PDA1, and a second pad portion PDA2.

In an embodiment, the scan driver 610 may be disposed on the first side of the display area DAA, and the emission driver 620 may be disposed on the second side of the display area DAA. For example, the scan driver 610 may be disposed on one side of the display area DAA in the first direction DR1, and the emission driver 620 may be disposed on the other side of the display area DAA in the first direction DR1. That is, as shown in FIG. 4, the scan driver 610 may be disposed on the left side of the display area DAA, and the emission driver 620 may be disposed on the right side of the display area DAA. However, the invention is not limited thereto, and the scan driver 610 and the emission driver 620 may be disposed on both the first side and the second side of the display area DAA.

In an embodiment, the first pad portion PDA1 may include the plurality of first pads PD1 connected to pads or bumps of the circuit board 300 through a conductive adhesive member. The first pad portion PDA1 may be disposed on the third side of the display area DAA. For example, the first pad portion PDA1 may be disposed on one side of the display area DAA in the second direction DR2. The first pad portion PDA1 may be disposed outside the data driver 700 in the second direction DR2. That is, as shown in FIG. 4, the first pad portion PDA1 may be disposed closer to the edge of the display panel 100 than the data driver 700.

In an embodiment, the second pad portion PDA2 may include a plurality of second pads PD2 corresponding to inspection pads that test whether the display panel 100 operates normally. The plurality of second pads PD2 may be connected to a jig or probe pins during an inspection process or may be connected to a circuit board for inspection. The circuit board for inspection may be a printed circuit board made of a rigid material or a flexible printed circuit board made of a flexible material.

The second pad portion PDA2 may be disposed on the fourth side of the display area DAA. For example, the second pad portion PDA2 may be disposed on the other side of the display area DAA in the second direction DR2. The second pad portion PDA2 may be disposed outside the second distribution circuit 720 in the second direction DR2. That is, as shown in FIG. 4, the second pad portion PDA2 may be disposed closer to the edge of the display panel 100 than the second distribution circuit 720.

In an embodiment, the first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be disposed on the third side of the display area DAA of the display panel 100. For example, the first distribution circuit 710 may be disposed on one side of the display area DAA in the second direction DR2. That is, as shown in FIG. 4, the first distribution circuit 710 may be disposed on the lower side of the display area DAA.

In an embodiment, the second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on the other side of the display area DAA in the second direction DR2. That is, as shown in FIG. 4, the second distribution circuit 720 may be disposed on the upper side of the display area DAA.

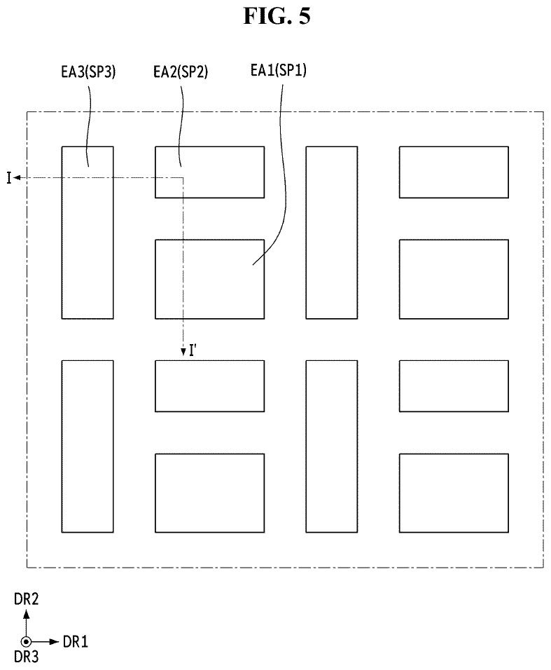

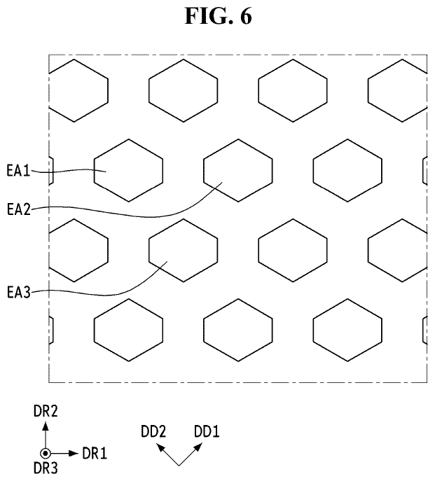

FIG. 5 is a schematic plan view illustrating an example of the display area shown in FIG. 4, according to an embodiment. FIG. 6 is a schematic plan view illustrating another example of the display area shown in FIG. 4, according to an embodiment.

In an embodiment and referring to FIG. 5, each of the plurality of pixels PX may include a first sub-pixel SP1, a second sub-pixel SP2, and a third sub-pixel SP3. The first to third sub-pixels SP1, SP2, and SP3 may include emission areas EA1, EA2, and EA3, respectively. For example, the first sub-pixel SP1 may include the first emission area EA1, the second sub-pixel SP2 may include the second emission area EA2, and the third sub-pixel SP3 may include the third emission area EA3.

In an embodiment, each of the first emission area EA1, the second emission area EA2, and the third emission area EA3 may be an area defined by a pixel defining film PDL (see FIG. 7). For example, each of the first emission area EA1, the second emission area EA2, and the third emission area EA3 may be an area defined by a first pixel defining film PDL1 (see FIG. 7).

In an embodiment, the length of the third emission area EA3 in the first direction DR1 may be less than the length of the first emission area EA1 in the first direction DR1, and the length of the second emission area EA2 in the first direction DR1. The length of the first emission area EA1 in the first direction DR1 and the length of the second emission area EA2 in the first direction DR1 may be substantially the same.

The length of the third emission area EA3 in the second direction DR2 may be greater than the length of the first emission area EA1 in the second direction DR2, and the length of the second emission area EA2 in the second direction DR2. The length of the first emission area EA1 in the second direction DR2 may be greater than the length of the second emission area EA2 in the second direction DR2.

In each of the plurality of pixels PX, the first emission area EA1 and the second emission area EA2 may be disposed adjacent to each other in the second direction DR2. Further, the first emission area EA1 and the third emission area EA3 may be adjacent to each other in the first direction DR1. Further, the second emission area EA2 and the third emission area EA3 may be disposed adjacent to each other in the first direction DR1. The area of the first emission area EA1, the area of the second emission area EA2, and the area of the third emission area EA3 may be different from each other.

In an embodiment, the first emission area EA1 may emit light of a first color, the second emission area EA2 may emit light of a second color, and the third emission area EA3 may emit light of a third color. Here, the light of the first color may be light of a red wavelength band, the light of the second color may be light of a green wavelength band, and the light of the third color may be light of a blue wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

As another example, as shown in FIG. 6, the first emission area EA1, the second emission area EA2, and the third emission area EA3 may be disposed in a hexagonal structure having a hexagonal shape in a plan view. In this case, the first emission area EA1 and the second emission area EA2 may be disposed adjacent to each other in the first direction DR1, but the second emission area EA2 and the third emission area EA3 may be disposed adjacent to each other in a first diagonal direction DD1, and the first emission area EA1 and the third emission area EA3 may be disposed adjacent to each other in a second diagonal direction DD2.

Although it is illustrated in FIGS. 5 and 6 that each of the plurality of pixels PX includes the three emission areas EA1, EA2, and EA3, the invention is not limited thereto. That is, each of the plurality of pixels PX may include four emission areas. Further, each of the emission areas EA1, EA2, and EA3 may have a polygonal, circular, elliptical, or atypical shape in a plan view, unlike those shown in FIGS. 5 and 6.

The arrangement of the emission areas EA1, EA2, and EA3 of the plurality of pixels PX is not limited to that illustrated in FIGS. 5 and 6. For example, in another embodiment, the emission areas of the plurality of pixels PX may be disposed in a stripe structure in which the emission areas are arranged in the first direction DR1, a PenTile® structure in which the emission areas are arranged in a diamond shape, or the like.

FIG. 7 is a cross-sectional view illustrating an example of the display panel taken along line I-I′ of FIG. 5, according to an embodiment.

In an embodiment and referring to FIG. 7, the display panel 100 may include a semiconductor backplane SBP, a light-emitting element backplane EBP, a display element layer EML, an encapsulation layer TFE, an adhesive layer APL, a cover layer CVL, and a polarizing plate POL.

In an embodiment, the semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the transistors T1 to T6 described with reference to FIG. 3.

In an embodiment, the semiconductor substrate SSUB may be a silicon substrate, a germanium substrate, or a silicon-germanium substrate. The semiconductor substrate SSUB may be a substrate doped with a first type impurity. A plurality of well regions WA may be disposed at top surface portions of the semiconductor substrate SSUB. The plurality of well regions WA may be regions doped with a second type impurity. The second type impurity may be different from the aforementioned first type impurity. For example, when the first type impurity is a p-type impurity, the second type impurity may be an n-type impurity. In another embodiment, when the first type impurity is an n-type impurity, the second type impurity may be a p-type impurity.

Each of the plurality of well regions WA may include a source region SA corresponding to the source electrode of the pixel transistor PTR, a drain region DA corresponding to the drain electrode thereof, and a channel region CH disposed between the source region SA and the drain region DA.

In an embodiment, a lower insulating film BINS may be disposed between a gate electrode GE and the well region WA. A side insulating film SINS may be disposed on the side surface of the gate electrode GE. The side insulating film SINS may be disposed on the lower insulating film BINS.

In an embodiment, each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be disposed on one side of the gate electrode GE, and the drain region DA may be disposed on the other side of the gate electrode GE.

In an embodiment, each of the plurality of well regions WA may further include a first low-concentration impurity region LDD1 disposed between the channel region CH and the source region SA, and a second low-concentration impurity region LDD2 disposed between the channel region CH and the drain region DA. The first low-concentration impurity region LDD1 may be a region having an impurity concentration lower than that of the source region SA. The second low-concentration impurity region LDD2 may be a region having an impurity concentration lower than that of the drain region DA. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that punch-through and hot carrier phenomena that might be caused by a short channel may be reduced or prevented.

In an embodiment, a first semiconductor insulating film SINS1 may be disposed on the semiconductor substrate SSUB. The first semiconductor insulating film SINS1 may be formed of silicon carbonitride (SiCN) or a silicon oxide (SiOx)-based inorganic film, but the invention is not limited thereto.

In an embodiment, a second semiconductor insulating film SINS2 may be disposed on the first semiconductor insulating film SINS1. The second semiconductor insulating film SINS2 may be formed of a silicon oxide (SiOx)-based inorganic film, but the invention is not limited thereto.

In an embodiment, the plurality of contact terminals CTE may be disposed on the second semiconductor insulating film SINS2. Each of the plurality of contact terminals CTE may be connected to any one of the gate electrode GE, the source region SA, and the drain region DA of each of the pixel transistors PTR through contact plugs penetrating the first semiconductor insulating film SINS1 and the second semiconductor insulating film INS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

In an embodiment, a third semiconductor insulating film SINS3 may be disposed on side surfaces of the plurality of contact terminals CTE. The top surface of each of the plurality of contact terminals CTE may be exposed without being covered by the third semiconductor insulating film SINS3. The third semiconductor insulating film SINS3 may be formed of a silicon oxide (SiOx)-based inorganic film, but the invention is not limited thereto.

In an embodiment, the semiconductor substrate SSUB may be replaced with a glass substrate or a polymer resin substrate such as polyimide. In this case, thin film transistors may be disposed on the glass substrate or the polymer resin substrate. The glass substrate may be a rigid substrate that does not bend, and the polymer resin substrate may be a flexible substrate that can be bent or curved.

In an embodiment, the light-emitting element backplane EBP may include a plurality of conductive layers ML1 to ML8, a plurality of vias VA1 to VA9, and a plurality of insulating films INS1 to INS9, where the plurality of insulating films INS1 to INS9 may be used for electrical insulation between the plurality of conductive layers ML1 to ML8.

In an embodiment, the conductive layers ML1 to ML8 are connected to the plurality of contact terminals CTE exposed from the semiconductor backplane SBP, and serve to implement the circuit of the first sub-pixel SP1 shown in FIG. 3. For example, the transistors T1 to T6 are merely formed in the semiconductor backplane SBP, and the connection of the transistors T1 to T6 and the capacitors C1 and C2 may be implemented by the conductive layers ML1 to ML8. In addition, the connection between the drain region corresponding to the drain electrode of the fourth transistor T4, the source region corresponding to the source electrode of the fifth transistor T5, and a first electrode AND of the light-emitting element LE (see FIG. 3) may also be implemented by the conductive layers ML1 to ML8.

In an embodiment, the first insulating film INS1 may be disposed on the semiconductor backplane SBP. Each of the first vias VA1 may penetrate the first insulating film INS1 and be connected to the contact terminal CTE exposed from the semiconductor backplane SBP. Each of the first conductive layers ML1 may be disposed on the first insulating film INS1 and may be connected to the first via VA1.

In an embodiment, the second insulating film INS2 may be disposed on the first insulating film INS1 and the first conductive layers ML1. Each of the second vias VA2 may penetrate the second insulating film INS2 and be connected to the first conductive layer ML1. Each of the second conductive layers ML2 may be disposed on the second insulating film INS2 and may be connected to the second via VA2.

In an embodiment, the third insulating film INS3 may be disposed on the second insulating film INS2 and the second conductive layers ML2. Each of the third vias VA3 may penetrate the third insulating film INS3 and be connected to the second conductive layer ML2. Each of the third conductive layers ML3 may be disposed on the third insulating film INS3 and may be connected to the third via VA3.

In an embodiment, a fourth insulating film INS4 may be disposed on the third insulating film INS3 and the third conductive layers ML3. Each of the fourth vias VA4 may penetrate the fourth insulating film INS4 and be connected to the third conductive layer ML3. Each of the fourth conductive layers ML4 may be disposed on the fourth insulating film INS4 and may be connected to the fourth via VA4.

In an embodiment, a fifth insulating film INS5 may be disposed on the fourth insulating film INS4 and the fourth conductive layers ML4. Each of the fifth vias VA5 may penetrate the fifth insulating film INS5 and be connected to the fourth conductive layer ML4. Each of the fifth conductive layers ML5 may be disposed on the fifth insulating film INS5 and may be connected to the fifth via VA5.

In an embodiment, a sixth insulating film INS6 may be disposed on the fifth insulating film INS5 and the fifth conductive layers ML5. Each of the sixth vias VA6 may penetrate the sixth insulating film INS6 and be connected to the fifth conductive layer ML5. Each of the sixth conductive layers ML6 may be disposed on the sixth insulating film INS6 and may be connected to the sixth via VA6.

In an embodiment, a seventh insulating film INS7 may be disposed on the sixth insulating film INS6 and the sixth conductive layers ML6. Each of the seventh vias VA7 may penetrate the seventh insulating film INS7 and be connected to the sixth conductive layer ML6. Each of the seventh conductive layers ML7 may be disposed on the seventh insulating film INS7 and may be connected to the seventh via VA7.

In an embodiment, an eighth insulating film INS8 may be disposed on the seventh insulating film INS7 and the seventh conductive layers ML7. Each of the eighth vias VA8 may penetrate the eighth insulating film INS8 and be connected to the seventh conductive layer ML7. Each of the eighth conductive layers ML8 may be disposed on the eighth insulating film INS8 and may be connected to the eighth via VA8.

The conductive layers ML1 to ML8 may be made of substantially the same material. The conductive layers ML1 to ML8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The vias VA1 to VA8 may be made of substantially the same material. The vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. Insulating films INS1 to INS8 may be formed of a silicon oxide (SiOx)-based inorganic film, but the invention is not limited thereto.

In an embodiment, the thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1360 Å. The thickness of each of the second conductive layer ML2, the third conductive layer ML3, the fourth conductive layer ML4, the fifth conductive layer ML5, and the sixth conductive layer ML6 may be approximately 1440 Å. The thickness of each of the first via VA1, the second via VA2, the third via VA3, the fourth via VA4, the fifth via VA5, and the sixth via VA6 may be approximately 1150 Å.

In an embodiment, the thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of each of the first via VA1, the second via VA2, the third via VA3, the fourth via VA4, the fifth via VA5, and the sixth via VA6. The thickness of the seventh conductive layer ML7 and the thickness of the eighth conductive layer ML8 may be substantially the same. For example, in an embodiment, the thickness of each of the seventh conductive layer ML7 and the eighth conductive layer ML8 may be approximately 9,000 Å. The thickness of each of the seventh via VA7 and the eighth via VA8 may be approximately 6,000 Å.

In an embodiment, a ninth insulating film INS9 may be disposed on the eighth insulating film INS8 and the eighth conductive layer ML8. The ninth insulating film INS9 may be formed of a silicon oxide (SiOx)-based inorganic film, but the invention is not limited thereto.

In an embodiment, each of the ninth vias VA9 may penetrate the ninth insulating film INS9 and be connected to the eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the ninth via VA9 may be approximately 16,500 Å.

In an embodiment, the display element layer EML may be disposed on the light-emitting element backplane EBP, where the display element layer EML may include a reflective electrode layer RL, a tenth insulating film INS10, a tenth via VA10, light-emitting elements LE, and a pixel defining film PDL. Each of the light-emitting elements LE may include a first electrode AND, a light-emitting stack ES, and a second electrode CAT.

In an embodiment, the reflective electrode layer RL may be disposed on the ninth insulating film INS9 and may include at least one reflective electrode RL1, RL2, RL3, and RL4, a first step layer STPL1, and a second step layer STPL2. For example, the reflective electrode layer RL may include reflective electrodes RL1, RL2, RL3, and RL4 as shown in FIG. 7.

Each of the first reflective electrodes RL1 may be disposed on the ninth insulating film INS9 and may be connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first reflective electrodes RL1 may include titanium nitride (TiN).

Each of the second reflective electrodes RL2 may be disposed on the first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the second reflective electrodes RL2 may include aluminum (Al).

In an embodiment, the first step layer STPL1 may be disposed on the second reflective electrode RL2 in the second sub-pixel SP2 and the third sub-pixel SP3. The first step layer STPL1 may not be disposed on the second reflective electrode RL2 in the first sub-pixel SP1.

In an embodiment, the second step layer STPL2 may be disposed on the first step layer STPL1 in the third sub-pixel SP3. The second step layer STPL2 may not be disposed on the second reflective electrode RL2 in the first sub-pixel SP1. In addition, the second step layer STPL2 may not be disposed on the first step layer STPL1 in the second sub-pixel SP2.

In an embodiment, he thickness of the first step layer STPL1 may be set in consideration of the wavelength of the light of the second color and a distance from the light-emitting stack ES of the second sub-pixel SP2 to the fourth reflective electrode RL4 to advantageously reflect the light of the second color emitted from the light-emitting stack ES. The thickness of the second step layer STPL2 may be set in consideration of the wavelength of the light of the third color and a distance from the light-emitting stack ES of the third sub-pixel SP3 to the fourth reflective electrode RL4 to advantageously reflect the light of the third color emitted from the light-emitting stack ES.

The first step layer STPL1 and the second step layer STPL2 may be formed of silicon carbonitride (SiCN) or a silicon oxide (SiOx)-based inorganic film, but the invention is not limited thereto.

In the first sub-pixel SP1, the third reflective electrode RL3 may be disposed on the second reflective electrode RL2. In the second sub-pixel SP2, the third reflective electrode RL3 may be disposed on the first step layer STPL1 and the second reflective electrode RL2. In the third sub-pixel SP3, the third reflective electrode RL3 may be disposed on the second step layer STPL2 and the second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the third reflective electrodes RL3 may include titanium nitride (TiN).

In an embodiment, at least one of the first reflective electrode RL1, the second reflective electrode RL2, and the third reflective electrode RL3 may be omitted.

Each of the fourth reflective electrodes RL4 may be disposed on the third reflective electrode RL3. The fourth reflective electrodes RL4 may be a layer that reflects light from the light-emitting stack ES. The fourth reflective electrodes RL4 may include metal having high reflectivity to advantageously reflect the light. In addition, since the fourth reflective electrode RL4 is an electrode that substantially reflects light from the light-emitting elements LE, the thickness of the fourth reflective electrode RL4 may be greater than the thickness of each of the first reflective electrode RL1, the second reflective electrode RL2, and the third reflective electrode RL3. The fourth reflective electrodes RL4 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the fourth reflective electrodes RL4 may include aluminum (Al) or titanium (Ti).

In an embodiment, the tenth insulating film INS10 may be disposed on the ninth insulating film INS9 and the fourth reflective electrodes RL4. The tenth insulating film INS10 may be an optical auxiliary layer through which light reflected by the reflective electrode layer RL passes, among light emitted from the light-emitting elements LE. The tenth insulating film INS10 may be formed of a silicon oxide (SiOx)-based inorganic film, but the invention is not limited thereto.

Each of the tenth vias VA10 may penetrate the tenth insulating film VA10 and be connected to the reflective electrode layer RL. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

In an embodiment, the thicknesses of the tenth vias VA10 may be different in the first sub-pixel SP1, the second sub-pixel SP2, and the third sub-pixel SP3 in order to adjust a resonance distance of light emitted from the light-emitting elements LE in at least one of the first sub-pixel SP1, the second sub-pixel SP2, or the third sub-pixel SP3. For example, the thickness of the tenth via VA10 in the third sub-pixel SP3 may be less than the thickness of the tenth via VA10 in each of the first sub-pixel SP1 and the second sub-pixel SP2. Further, the thickness of the tenth via VA10 in the second sub-pixel SP2 may be smaller than the thickness of the tenth via VA10 in the first sub-pixel SP1. That is, the distance between the light-emitting stack ES and the reflective electrode layer RL may be different in the first sub-pixel SP1, the second sub-pixel SP2, and the third sub-pixel SP3.

In summary, in order to adjust the distance between the light-emitting stack ES and the reflective electrode layer RL according to the main wavelength of light emitted from the first sub-pixel SP1, the second sub-pixel SP2, and the third sub-pixel SP3, the presence or absence of the step layers STPL1 and STPL2 and the thickness of each of the step layers STPL1 and STPL2 in the first sub-pixel SP1, the second sub-pixel SP2, and the third sub-pixel SP3 may be set.

In an embodiment, the first electrode AND of each of the light-emitting elements LE may be disposed on the tenth insulating film INS10 and connected to the tenth via VA10. The first electrode AND of each of the light-emitting elements LE may be connected to the drain region DA or source region SA of the pixel transistor PTR through the tenth via VA10, the reflective electrodes RL1 to RL4, the vias VA1 to VA9, the conductive layers ML1 to ML8, and the contact terminal CTE. The first electrode AND of each of the light-emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light-emitting elements LE may be titanium nitride (TiN).

In an embodiment, the pixel defining film PDL may be disposed on the tenth insulating film INS10 and a part of the first electrode AND of each of the light-emitting elements LE. The pixel defining film PDL may cover the edge of the first electrode AND of each of the light-emitting elements LE. The pixel defining film PDL may serve to partition the first emission areas EA1, the second emission areas EA2, and the third emission areas EA3. That is, the pixel defining film PDL may have openings that partially expose the first electrode AND of each of the light-emitting elements LE.

In an embodiment, the first emission area EA1 may be defined as an area in which the first electrode AND, the light-emitting stack ES, and the second electrode CAT are sequentially stacked in the first sub-pixel SP1 to emit light. The second emission area EA2 may be defined as an area in which the first electrode AND, the light-emitting stack ES, and the second electrode CAT are sequentially stacked in the second sub-pixel SP2 to emit light. The third emission area EA3 may be defined as an area in which the first electrode AND, the light-emitting stack ES, and the second electrode CAT are sequentially stacked in the third sub-pixel SP3 to emit light.

In an embodiment, the pixel defining film PDL may include pixel defining films PDL1, PDL2, and PDL3. The first pixel defining film PDL1 may be disposed on the tenth insulating film INS10 and the first electrode AND of each of the light-emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of a silicon oxide (SiOx)-based inorganic film, but the invention is not limited thereto. The first pixel defining film PDL1, the second pixel defining film PDL2, and the third pixel defining film PDL3 may each have a thickness of about 500 Å.

In an embodiment, when the first pixel defining film PDL1, the second pixel defining film PDL2, and the third pixel defining film PDL3 are formed as one pixel defining film, the height of the one pixel defining film increases, so that a first encapsulation inorganic film TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, in order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. For example, the widths of the openings of the first pixel defining film PDL1 may be less than the widths of the openings of the second pixel defining film PDL2, and the widths of the openings of the second pixel defining film PDL2 may be less than the widths of the openings of the third pixel defining film PDL3.

In an embodiment, the light-emitting stack ES may include a first light-emitting stack ES1 disposed in the first emission area EA1, a second light-emitting stack ES2 disposed in the second emission area EA2, and a third light-emitting stack ES3 disposed in the third emission area EA3. Although not shown in detail, the first light-emitting stack ES1 may include a hole injecting layer HIL, a hole transporting layer HTL, a first light-emitting layer EML1, an electron transporting layer ETL, and an electron injecting layer EIL, the second light-emitting stack ES2 may include the hole injecting layer HIL, the hole transporting layer HTL, a second light-emitting layer EML2, the electron transporting layer ETL, and the electron injecting layer EIL, and the third light-emitting stack ES3 may include the hole injecting layer HIL, the hole transporting layer HTL, a third light-emitting layer EML3, the electron transporting layer ETL, and the electron injecting layer EIL.

For example, the hole injecting layer HIL may be disposed on the first electrodes AND exposed by the openings of the pixel defining film PDL, the inner surfaces of the openings of the pixel defining film PDL, and the top surface of the pixel defining film PDL. The hole transporting layer HTL may be disposed on the hole injecting layer HIL.

In an embodiment, the light-emitting layers EML1, EML2, and EML3 may be respectively disposed in the openings of the pixel defining film PDL on the hole transporting layer HTL. The first light-emitting layer EML1 may be disposed in the opening of the pixel defining film PDL in the first emission area EA1, and may emit light of a first color, for example, red light. The second light-emitting layer EML2 may be disposed in the opening of the pixel defining film PDL in the second emission area EA2, and may emit light of a second color, for example, green light. The third light-emitting layer EML3 may be disposed in the opening of the pixel defining film PDL in the third emission area EA3, and may emit light of a third color, for example, blue light.

In an embodiment, the electron transporting layer ETL may be disposed on the light-emitting layers EML1, EML2, and EML3 and the hole transporting layer HTL, and the electron injecting layer EIL may be disposed on the electron transporting layer ETL.

For another example, although not shown, a plurality of trenches (not shown) may be disposed between the emission areas EA1, EA2, and EA3. The trenches may have a ring shape respectively surrounding the emission areas EA1, EA2, and EA3, and may be formed to penetrate the pixel defining film PDL. The hole injecting layer HIL and the hole transporting layer HTL formed on the first electrodes AND of the emission areas EA1, EA2, and EA3 may be disconnected from each other by the trenches.

For another example, the light-emitting stacks ES1, ES2, and ES3 may be respectively disposed in the openings of the pixel defining film PDL and may not be disposed on the pixel defining film PDL. In this case, the light-emitting stacks ES1, ES2, and ES3 may be disconnected from each other by the pixel defining film PDL.

In an embodiment, the second electrode CAT may be disposed on the light-emitting stacks ES1, ES2, and ES3. The second electrode CAT may be formed of a transparent conductive material (TCO) such as ITO or IZO that can transmit light or a semi-transmissive conductive material such as magnesium (Mg), silver (Ag), or an alloy of Mg and Ag. When the second electrode CAT is formed of a semi-transmissive conductive material, the light emission efficiency may be improved in each of the sub-pixels SP1, SP2, and SP3 due to a micro-cavity effect.

In an embodiment, the encapsulation layer TFE may be disposed on the display element layer EML, where the encapsulation layer TFE may include at least one inorganic film TFE1 and TFE2 to reduce or prevent oxygen or moisture from permeating into the display element layer EML. For example, the encapsulation layer TFE may include the first encapsulation inorganic film TFE1, and a second encapsulation inorganic film TFE2.

The first encapsulation inorganic film TFE1 may be disposed on the second electrode CAT. The first encapsulation inorganic film TFE1 may be formed as a multilayer in which one or more inorganic films selected from silicon nitride (SiNx), silicon oxynitride (SiON), and silicon oxide (SiOx) are alternately stacked. The first encapsulation inorganic film TFE1 may be formed by a chemical vapor deposition (CVD) process.

The second encapsulation inorganic film TFE2 may be disposed on the first encapsulation inorganic film TFE1. The second encapsulation inorganic film TFE2 may be formed of titanium oxide (TiOx) or aluminum oxide (AlOx), but the embodiment of the present specification is not limited thereto. The second encapsulation inorganic film TFE2 may be formed by an atomic layer deposition (ALD) process. The thickness of the second encapsulation inorganic film TFE2 may be less than the thickness of the first encapsulation inorganic film TFE1.

In an embodiment, the adhesive layer APL may be a layer for increasing the interfacial adhesion between the encapsulation layer TFE and the cover layer CVL. The adhesive layer APL may be an organic film such as acrylic resin, epoxy resin, phenolic resin, polyamide resin, or polyimide resin.

In an embodiment, the cover layer CVL may be disposed on the adhesive layer APL, where the cover layer CVL may be a glass substrate or a polymer resin. When the cover layer CVL is a glass substrate, it may be attached onto the adhesive layer APL and may serve as an encapsulation substrate. When the cover layer CVL is a polymer resin, it may be directly applied onto the adhesive layer APL.

In an embodiment, the polarizing plate POL may be disposed on the cover layer CVL and may be a structure for reducing or preventing visibility degradation caused by reflection of external light. The polarizing plate POL may include a linear polarizing plate and a phase retardation film. For example, the phase retardation film may be a λ/4 plate (quarter-wave plate), but the invention is not limited thereto.

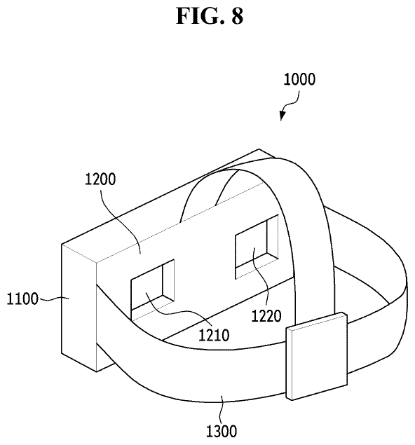

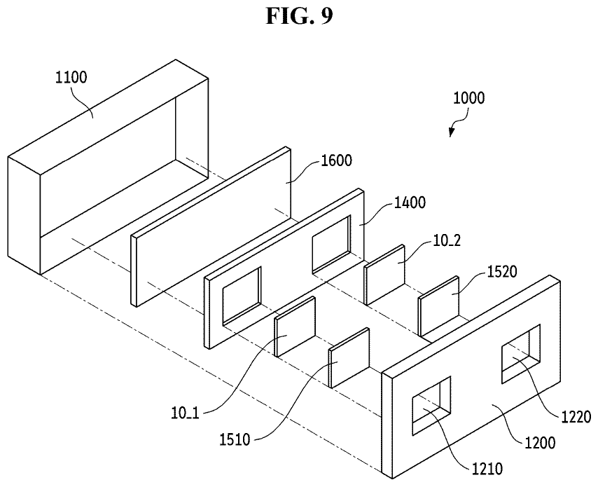

FIG. 8 is a schematic perspective view illustrating a head mounted display, according to an embodiment. FIG. 9 is a schematic exploded perspective view illustrating an example of the head mounted display shown in FIG. 8, according to an embodiment.

In an embodiment and referring to FIGS. 8 and 9, a head mounted display 1000 may include a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

In an embodiment, the first display device 10_1 may provide an image to the user's left eye, and the second display device 10_2 provides an image to the user's right eye. Since each of the first display device 10_1 and the second display device 10_2 is substantially the same as the display device 10 described in conjunction with FIGS. 1 and 2, description of the first display device 10_1 and the second display device 10_2 will be omitted.

In an embodiment, the first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

In an embodiment, the middle frame 1400 may be disposed between the display devices 10_1 and 10_2 and the control circuit board 1600. The middle frame 1400 serves to support and fix the first display device 10_1, the second display device 10_2, and the control circuit board 1600.

In an embodiment, the control circuit board 1600 may be disposed between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA and transmit the digital video data DATA to the first display device 10_1 and the second display device 10_2 through the connector.

In an embodiment, the control circuit board 1600 may transmit the digital video data DATA corresponding to a left-eye image optimized for the user's left eye to the first display device 10_1 and may transmit the digital video data DATA corresponding to a right-eye image optimized for the user's right eye to the second display device 10_2. In another embodiment, the control circuit board 1600 may transmit the same digital video data DATA to the first display device 10_1 and the second display device 10_2.

In an embodiment, the display device housing 1100 serves to accommodate the first display device 10_1, the second display device 10_2, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is located and the second eyepiece 1220 at which the user's right eye is located. FIGS. 8 and 9 illustrate that the first eyepiece 1210 and the second eyepiece 1220 are disposed separately, but the invention is not limited thereto. For example, in another embodiment, the first eyepiece 1210 and the second eyepiece 1220 may be combined into one unit.

In an embodiment, the first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

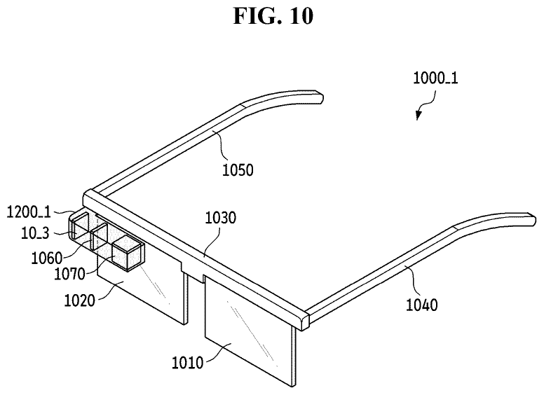

In an embodiment, the head mounted band 1300 serves to secure the display device housing 1100 to the user's head such that the first eyepiece 1210 and the second eyepiece 1220 of the housing cover 1200 remain located on the user's left and right eyes, respectively. When the display device housing 1100 is implemented to be lightweight and compact, the head mounted display 1000 may be provided in the form of glasses as shown in FIG. 10.

In addition, in an embodiment, the head mounted display 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 10 is a schematic perspective view illustrating another example of a head mounted display, according to an embodiment.

In an embodiment and referring to FIG. 10, a head mounted display 1000_1 may be an eyeglasses-type display device in which a display device housing 1200_1 is implemented in a lightweight and compact manner. The head mounted display 1000_1 may include a display device 10_3, a left eye lens 1010, a right eye lens 1020, a support frame 1030, temples 1040 and 1050, an optical member 1060, an optical path conversion member 1070, and the display device housing 1200_1.

In an embodiment, the display device housing 1200_1 may include the display device 10_3, the optical member 1060, and the optical path conversion member 1070. The image displayed on the display device 10_3 may be magnified by the optical member 1060 and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 10 illustrates an embodiment where the display device housing 1200_1 is disposed at the right end of the support frame 1030, but the invention is not limited thereto. For example, the display device housing 1200_1 may be disposed at the left end of the support frame 1030, and in this case, the image of the display device 10_3 may be provided to the user's left eye. As another example, the display device housing 1200_1 may be disposed at both the left and right ends of the support frame 1030, and in this case, the user may view the image displayed on the display device 10_3 through both the left and right eyes.

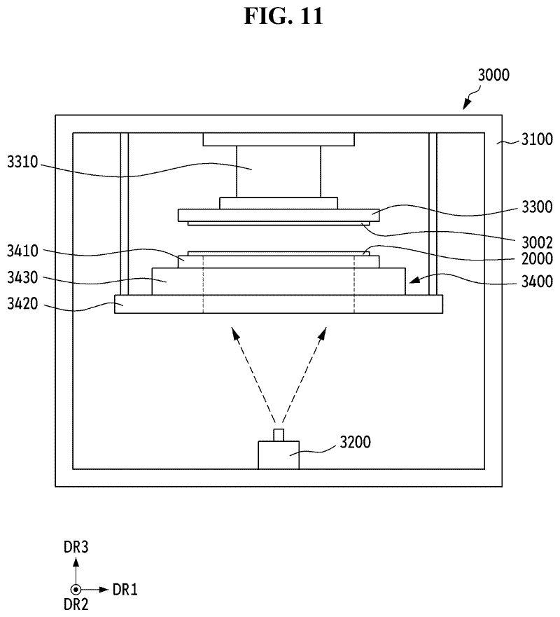

FIG. 11 is a schematic view illustrating a deposition mask and a deposition apparatus including the same, according to an embodiment.

In an embodiment and referring to FIG. 11, a deposition apparatus 3000 may be used to form light emitting material layers on a backplane substrate 3002 in a manufacturing process of the display panel 100 (see FIG. 1). For example, as illustrated in FIG. 7, the semiconductor backplane SBP and the light emitting element backplane EBP may be disposed on the backplane substrate 3002, and the reflective electrode layer RL and the insulating film INS10 may be disposed on the light emitting element backplane EBP. Electrode patterns, for example, the anode electrodes AND may be disposed on the insulating film INS10, and the anode electrodes AND may be electrically connected to the reflective electrode layer RL through the vias VA10. The deposition apparatus 3000 may be used to form the light-emitting layers of the light emitting stacks ES1, ES2 and ES3 on the electrode patterns of the backplane substrate 3002.

In an embodiment, the deposition apparatus 3000 may include a deposition source 3200 for providing a vapor deposition material on the backplane substrate 3002, a deposition mask 2000 disposed above the deposition source 3200, and a substrate chuck 3300 disposed above the deposition mask 2000 to support the backplane substrate 3002 such that the backplane substrate 3002 faces the deposition mask 2000. That is, the substrate chuck 3300 may support the backplane substrate 3002 such that a front surface of the backplane substrate 3002 faces downward, and may position the backplane substrate 3002 on the deposition mask 2000 to perform a deposition process.

In an embodiment, the deposition source 3200, the deposition mask 2000, and the substrate chuck 3300 may be disposed in a process chamber 3100. The process chamber 3100 may have an internal space, and a deposition process for forming a deposition material layer on the backplane substrate 3002 may be performed in the internal space of the process chamber 3200. Although not shown, the process chamber 3100 may be connected to a vacuum pump (not shown), and the internal space of the process chamber 3100 may be set to a vacuum atmosphere by the vacuum pump. An opening (not shown) for the carry-in and carry-out of the backplane substrate 3002 and the deposition mask 2000 may be provided in a wall of the process chamber 3100, and the opening may be opened and closed by a gate valve (not shown).

In an embodiment, a deposition material may be accommodated in the deposition source 3200. The deposition source 3200 may evaporate a deposition material such as an organic material, an inorganic material, a conductive material, or the like toward the backplane substrate 3002, and the evaporated deposition material may be deposited on the backplane substrate 3002 through the deposition mask 2000. For example, the deposition source 3200 may evaporate an organic material for forming light emitting material layers on the backplane substrate 3002, and the evaporated organic material may be deposited on the electrode patterns on the backplane substrate 3002 through the deposition mask 2000.

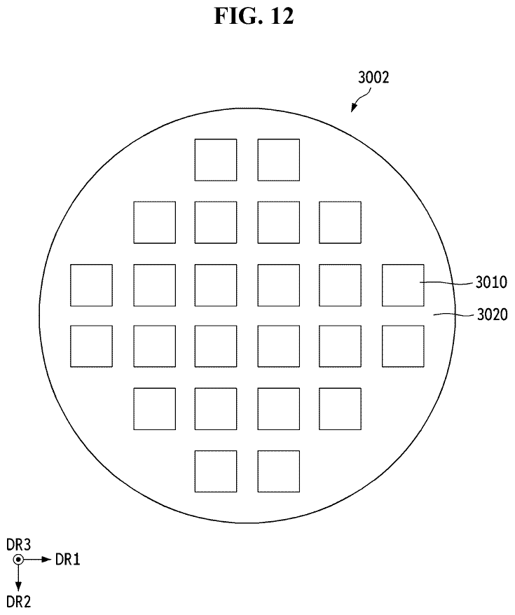

FIG. 12 is a schematic bottom view illustrating the backplane substrate as shown in FIG. 11, according to an embodiment.

In an embodiment and referring to FIG. 12, the backplane substrate 3002 may include a plurality of display cell regions 3010 and a scribe lane region 3020 disposed between the display cell regions 3010. As shown in FIG. 12, the display cell regions 3010 may be arranged in a matrix form along a first direction DR1 and a second direction DR2 crossing the first direction DR1, and the display cell regions 3010 may be respectively individualized into a plurality of display panels 100 (see FIG. 1) through a dicing process after a display manufacturing process is completed. For example, the first direction DR1 may be a first horizontal direction, and the second direction DR2 may be a second horizontal direction perpendicular to the first direction DR1.

In an embodiment, each of the display cell regions 3010 may include the semiconductor backplane SBP, the light emitting element backplane EBP disposed on the semiconductor backplane SBP, the reflective electrode layer RL disposed on the light emitting element backplane EBP, and the insulating film INS10 disposed on the reflective electrode layer RL. In addition, each of the display cell regions 3010 may include the plurality of electrode patterns, for example, the plurality of anode electrodes AND disposed on the insulating film INS10, and the anode electrodes AND may be connected to the reflective electrode layer RL through the plurality of vias VA10. In this case, the electrode patterns of the display cell regions 3010 may be disposed on the front surface of the backplane substrate 3002, and the substrate chuck 3300 may hold a rear surface of the backplane substrate 3002 such that the electrode patterns of the display cell regions 3010 face downward, i.e., face the deposition source 3200.

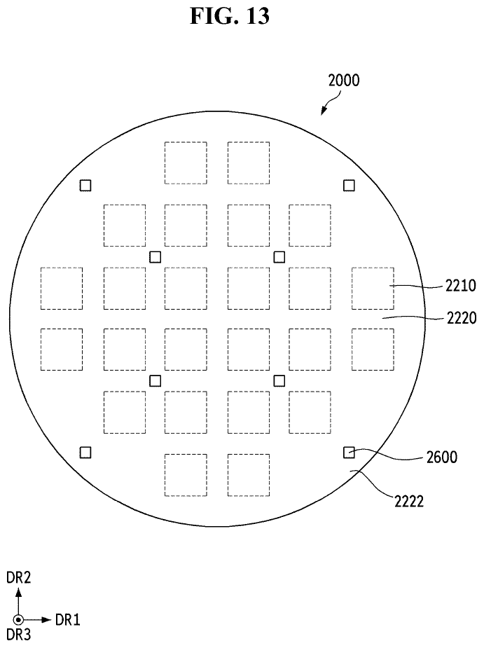

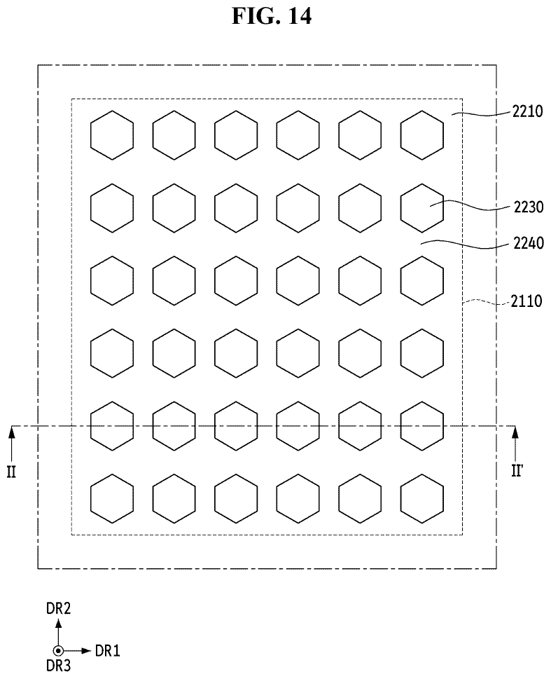

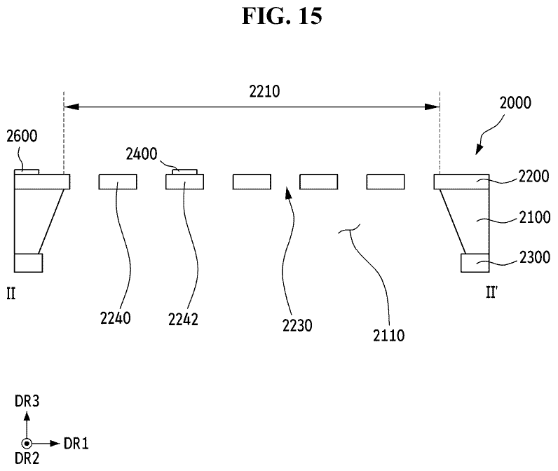

FIG. 13 is a schematic plan view illustrating the deposition mask as shown in FIG. 11, according to an embodiment. FIG. 14 is a schematic enlarged plan view illustrating mask cell regions as shown in FIG. 13, according to an embodiment, and FIG. 15 is a schematic cross-sectional view taken along line II-II′ as shown in FIG. 14, according to an embodiment.

In an embodiment and referring to FIGS. 13 to 15, the deposition mask 2000 may include mask cell regions 2210 respectively corresponding to the display cell regions 3010 of the backplane substrate 3002, where each of the mask cell regions 2210 may have a plurality of pixel openings 2230 that expose the anode electrodes AND in the deposition process.

For example, the deposition mask 2000 may include a mask frame 2100 and a membrane 2200 disposed on the mask frame 2100. In this case, the membrane 2200 may include a plurality of mask cell regions 2210 and a grid region 2220 disposed between the mask cell regions 2210, and each of the mask cell regions 2210 may have a plurality of pixel openings 2230. The mask frame 2100 may have cell openings 2110, and the mask cell regions 2210 may be disposed on the cell openings 2110, respectively. That is, the mask cell regions 2210 may be exposed toward the deposition source 3200 through the cell openings 2110, and the pixel openings 2230 may penetrate the mask cell regions 2210 to be connected to the cell openings 2110.

In an embodiment and as shown in FIG. 13, the mask cell regions 2210 may be arranged in a matrix form along a first direction DR1 and a second direction DR2. For example, the mask cell regions 2210 may be arranged in a matrix form along a first horizontal direction and a second horizontal direction perpendicular to the first horizontal direction and may be arranged to correspond to the display cell regions 3010 of the backplane substrate 3002, respectively.

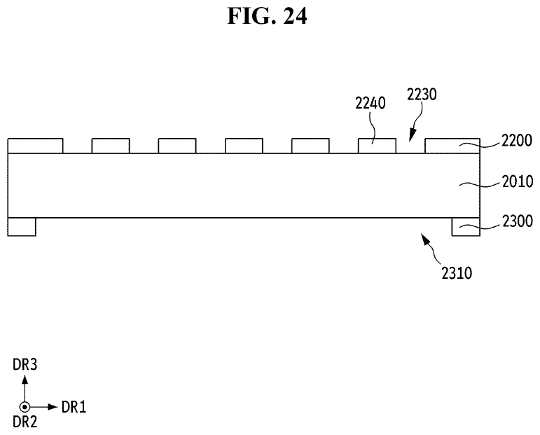

In an embodiment, the membrane 2200 may be disposed on a front surface of the mask frame 2100, and a rear inorganic film 2300 may be disposed on a rear surface of the mask frame 2100. The rear inorganic film 2300 may have rear openings 2310 (see FIG. 24) communicating with the cell openings 2110 and may function as an etching mask in an etching process for forming the cell openings 2110.

In an embodiment, the membrane 2200 and the rear inorganic film 2300 may be made of the same material. For example, the membrane 2200 and the rear inorganic film 2300 may be made of silicon nitride (SiNx) and may be formed to have a thickness of about 0.5 μm to about 3 μm through a thermal chemical vapor deposition (TCVD) process. A single crystal silicon substrate may be used as the mask frame 2100, and the cell openings 2110 may be formed to expose the mask cell regions 2210 of the membrane 2200 through an anisotropic etching process using the rear inorganic film 2300 as an etching mask.

By way of example, the cell openings 2110 may be formed through a wet etching process using tetramethylammonium hydroxide (TMAH) or potassium hydroxide (KOH). In this case, the <100> crystal direction of the single crystal silicon substrate used as the mask frame 2100 may be a third direction DR3, and accordingly, the cell openings 2110 may be formed by the wet etching process to have a width that gradually decreases from the rear surface of the mask frame 2100 toward the membrane 2200, i.e., in the third direction DR3. For example, each of inner surfaces of the cell openings 2110 may be formed to have an inclination of about 54.74°.

In an embodiment, the membrane 2200 may include a rib region 2240 that defines the pixel openings 2230. For example, each of the mask cell regions 2210 may include a rib region 2240 disposed between the pixel openings 2230. According to an embodiment, at least one heterogeneous material pattern 2400 made of a material different from the membrane 2200 may be disposed on the rib region 2240, where the heterogeneous material pattern 2400 may be formed on a first portion 2242 of the rib region 2240 to correct a gap between the pixel openings 2230 when the gap between the pixel openings 2230 is wider than a predetermined gap. For example, the heterogeneous material pattern 2400 may extend in a direction that is perpendicular to a direction of the gap between neighboring pixel openings 2230.

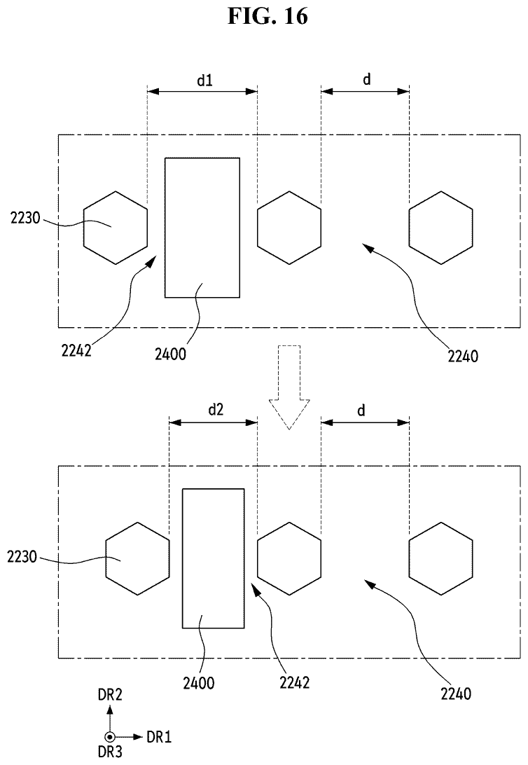

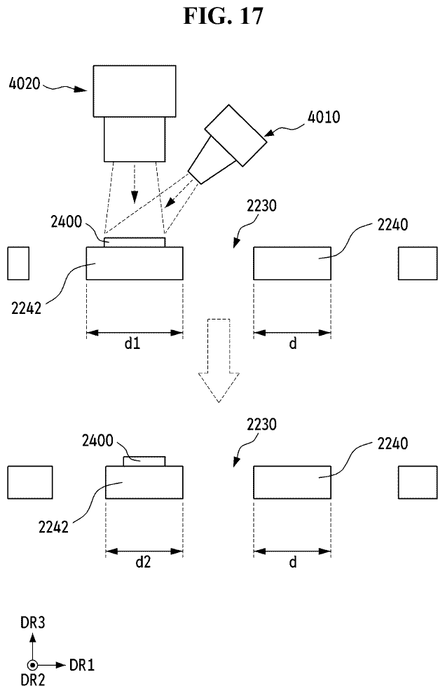

FIG. 16 is a schematic enlarged plan view illustrating the heterogeneous material pattern as shown in FIG. 15, according to an embodiment. FIG. 17 is a schematic enlarged cross-sectional view illustrating the heterogeneous material pattern as shown in FIG. 15, according to an embodiment.

In an embodiment and referring to FIGS. 16 and 17, a residual stress may be generated in the membrane 2200 while the membrane 2200 is being formed, resulting in an increase or a decrease of the gap between the pixel openings 2230. Such deformation of the membrane 2200 may occur locally, and when the gap between the pixel openings 2230 is wider than the predetermined gap, the heterogeneous material pattern 2400 may be formed on the corresponding portion.

By way of example, in an embodiment, after the cell openings 2110 are formed, the gap between the pixel openings 2230 and the PPA of the pixel openings 2230 may be measured using an inspection camera, and thus, portions where the gap between the pixel openings 2230 falls outside a predetermined tolerance range may be detected. According to the present embodiment, when a first portion 2242 where a gap d1 between the pixel openings 2230 is wider than a predetermined gap, that is, a normal gap d, is detected, the heterogeneous material pattern 2400 may be formed on the first portion 2242, as shown in FIGS. 16 and 17.

In particular, the heterogeneous material pattern 2400 may be formed of a material having a higher coefficient of thermal expansion than the membrane 2200. For example, the heterogeneous material pattern 2400 may include metal, and may be formed to have a thickness of about 0.1 μm to about 2 μm and a width of about 0.1 μm to about 3 μm through a laser chemical vapor deposition (LCVD) process. In this case, the thickness and the width of the heterogeneous material pattern 2400 may be determined according to the gap d1 between the pixel openings 2230, that is, the width d1 of the first portion 2242. By way of a non-limiting example, the heterogeneous material pattern 2400 may include tungsten (W), molybdenum (Mo), zirconium (Zr), hafnium (Hf), chromium (Cr), tantalum (Ta), titanium (Ti), platinum (Pt), yttrium (Y), palladium (Pd), nickel (Ni), cobalt (Co), gold (Au), copper (Cu), silver (Ag), tin (Sn), aluminum (Al), or zinc (Zn). Also, the heterogeneous material pattern 2400 may include an oxide or nitride of the aforementioned metal.

Specifically, in an embodiment, a precursor gas containing the metal may be provided onto the first portion 2242 through a nozzle 4010, and a laser beam may be irradiated onto the first portion 2242 from a laser device 4020. For example, a CO₂ laser or an Nd:YAG laser may be used in the LCVD process, and the first portion 2242 may be locally heated by the laser beam. In addition, the precursor gas may be decomposed by the irradiation of the laser beam, and a metal component of the precursor gas may be deposited on the first portion 2242.

In an embodiment, while the first portion 2242 and the heterogeneous material pattern 2400 are being cooled after the heterogeneous material pattern 2400 is formed, the first portion 2242 and the heterogeneous material pattern 2400 may contract, and the width d1 of the first portion 2242 may be reduced due to a difference in the coefficient of thermal expansion between the first portion 2242 and the heterogeneous material pattern 2400. For example, as shown in FIGS. 16 and 17, the width d1 of the first portion 2242 may be reduced to a width d2 which is the same as the normal width d of the rib region 2240. In particular, in order to reduce the width d1 of the first portion 2242, the heterogeneous material pattern 2400 may extend in a direction that is perpendicular to a direction of the gap between the pixel openings 2230 located on both sides of the first portion 2242, that is, in the second direction DR2 in FIG. 16.

Meanwhile, although not shown, in an embodiment, a second heterogeneous material pattern (not shown) may be formed on the heterogeneous material pattern 2400 when the gap d1 between the pixel openings 2230 is not sufficiently reduced by the heterogeneous material pattern 2400. In this case, the second heterogeneous material pattern may be made of the same material as the heterogeneous material pattern 2400 or a material having a higher coefficient of thermal expansion than the heterogeneous material pattern 2400.

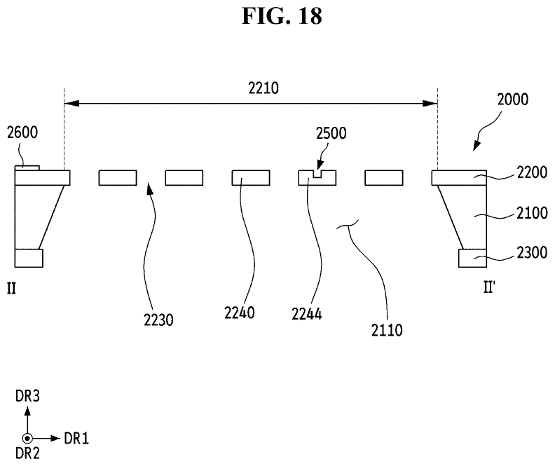

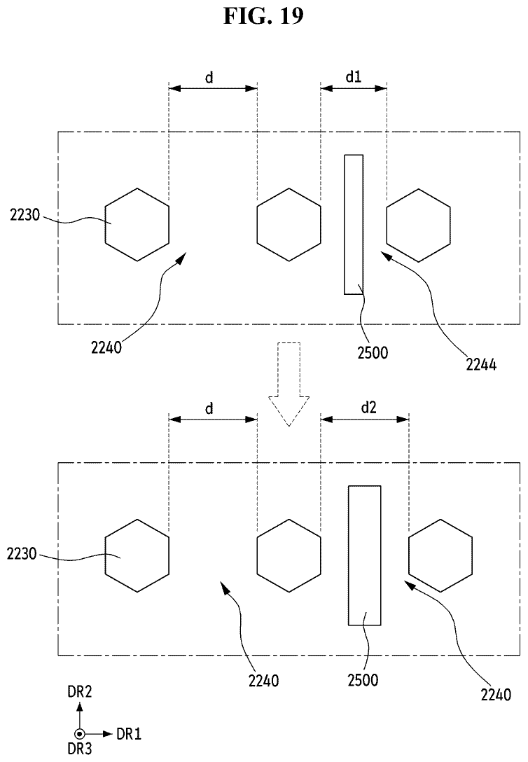

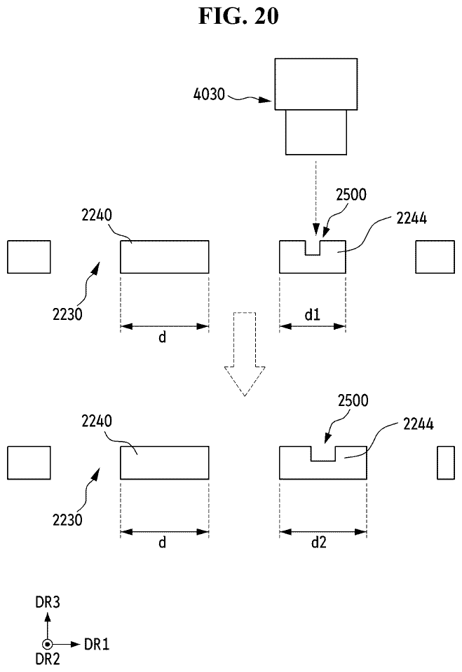

FIG. 18 is a cross-sectional view illustrating a deposition mask, according to another embodiment. FIG. 19 is a schematic enlarged plan view illustrating a groove as shown in FIG. 18, according to an embodiment. FIG. 20 is a schematic enlarged cross-sectional view illustrating the groove as shown in FIG. 18, according to an embodiment.

In an embodiment and referring to FIGS. 18 to 20, when a gap d1 between the pixel openings 2230 is narrower than a predetermined gap, a groove 2500 may be formed in the corresponding portion, and the gap d1 between the pixel openings 2230 may be corrected using the groove 2500. The groove 2500 may extend in a direction perpendicular to a direction of the gap between the neighboring pixel openings 2300, i.e., in the second direction DR2 as shown in FIG. 19, to increase the gap between the neighboring pixel openings 2300.

For example, in an embodiment, after the cell openings 2110 are formed, the gap between the pixel openings 2230 and the PPA of the pixel openings 2230 may be measured using an inspection camera, and when there is detected a second portion 2244 where the gap d1 between the pixel openings 2230 is narrower than the predetermined gap, i.e., the normal gap d, the groove 2500 may be formed to increase the width d1 of the second portion 2244. The groove 2500 may be formed through a laser ablation (LA) process. By way of example, in an embodiment, a laser beam may be irradiated onto the second portion 2244 from a laser device 4030, and the second portion 2244 may be partially removed by the irradiation of the laser beam, thereby forming the groove 2500.

In an embodiment, in the LA process, an ultrashort pulse laser such as a picosecond laser or a femtosecond laser may be used, and the groove 2500 may be formed to have a width of about 0.1 μm to about 2 μm and a depth of about 0.1 μm to about 2 μm. In particular, when the depth of the groove 2500 is less than about 0.1 times the thickness of the membrane 2200, the gap d1 between the pixel openings 2230 may not be sufficiently expanded, and when the depth of the groove 2500 is greater than about 0.7 times the thickness of the membrane 2200, a new opening may be formed between the pixel openings 2230. Thus, it is desirable that the groove 2500 is formed to have a depth of about 0.1 to about 0.7 times the thickness of the membrane 2200.

In an embodiment, after the groove 2500 is formed by the LA process, the width d1 of the second portion 2244 may be increased to the gap d2, which is the same as the normal gap d, due to the residual stress of the membrane 2200. In particular, in order to increase the width d1 of the second portion 2244, the groove 2500 may extend in a direction perpendicular to a direction of the gap between the pixel openings 2230 located on both sides of the second portion 2244, that is, in the second direction DR2 in FIG. 19.

Meanwhile, although one groove 2500 is formed between the pixel openings 2230 in the shown example, a plurality of grooves (not shown) may be formed parallel to each other between the pixel openings 2230. In this case, the width and the depth of each of the grooves and the number of the grooves may be decided according to the gap between the pixel openings 2230.

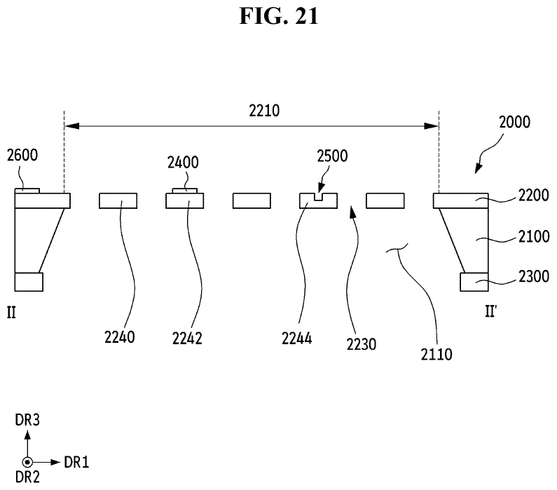

FIG. 21 is a schematic cross-sectional view illustrating a deposition mask, according to still another embodiment.

In an embodiment and referring to FIG. 21, a residual stress may be generated inside the membrane 2200 while the membrane 2200 is being formed, and, as a result, the gap between the pixel openings 2230 may be increased or decreased. Such deformation of the membrane 2200 may occur locally, and, as a result, at least one first portion 2242 where the gap between the pixel openings 2230 is wider than the predetermined gap and at least one second portion 2244 where the gap between the pixel openings 2230 is narrower than the predetermined gap may be generated. In this case, as shown in FIG. 21, the heterogeneous material pattern 2400 may be formed on the first portion 2242 through an LCVD process, and the groove 2500 may be formed in the second portion 2244 through an LA process.

In an embodiment and referring back to FIGS. 13 to 15, when the heterogeneous material pattern 2400 is formed on the membrane 2200, a gap between the backplane substrate 3002 and the deposition mask 2000 may become non-uniform in the deposition process. According to one embodiment, spacers 2600 for uniformizing the gap between the backplane substrate 3002 and the deposition mask 2000 may be disposed on the membrane 2200.

For example, the spacers 2600 may be disposed in the grid region 2220 and an edge region 2222 of the membrane 2200 and may be formed through an LCVD process. In particular, the spacers 2600 are desirably formed of the same material as the membrane 2200 to prevent deformation of the membrane 2200. As another example, the spacers 2600 may be formed of the same material as the heterogeneous material pattern 2400. As still another example, the spacers 2600 may be formed of a material having a coefficient of thermal expansion similar to that of the membrane 2200 to reduce deformation of the membrane 2200. By way of non-limiting example, when the membrane 2200 is made of silicon nitride (SiNx), the spacers 2600 may be made of a material such as silicon (Si), aluminum nitride (AlN), tungsten (W), molybdenum (Mo), or the like, which has a coefficient of thermal expansion similar to that of the silicon nitride (SiNx).

In an embodiment and referring back to FIG. 11, the substrate chuck 3300 may be disposed above the deposition source 3200 and may support the backplane substrate 3002, allowing the backplane substrate 3002 to face the deposition source 3200. For example, the substrate chuck 3300 may be an electrostatic chuck configured to hold the rear surface of the backplane substrate 3002 using an electrostatic force. To elaborate, the electrode patterns, i.e., the anode patterns AND may be disposed on the front surface of the backplane substrate 3002, and the substrate chuck 3300 may hold the rear surface of the backplane substrate 3002 so that the front surface of the backplane substrate 3002 faces the deposition source 3200, i.e., faces downward.

Although not shown, in an embodiment, the backplane substrate 3002 may be carried into the process chamber 3100 by a transfer robot (not shown), and lift fingers (not shown) for transferring the backplane substrate 3002 from the transfer robot to the substrate chuck 3300 may be disposed in the process chamber 3100. For example, the backplane substrate 3002 may be placed on the lift fingers after being brought into the process chamber 3100 by the transfer robot, and the lift fingers may be raised to load the backplane substrate 3002 on the substrate chuck 3300. Subsequently, the substrate chuck 3300 may hold the rear surface of the backplane substrate 3002 by using the electrostatic force.

In an embodiment, an upper driving unit 3310 for moving and rotating the substrate chuck 3300 may be disposed above the substrate chuck 3300 to adjust the position and angle of the backplane substrate 3002. For example, the upper driving unit 3310 may move the substrate chuck 3300 in the directions DR1 and DR2 to adjust the horizontal position of the backplane substrate 3002, and may move the substrate chuck 3300 in the third direction DR3 to adjust the vertical position of the backplane substrate 3002. In this case, the first direction DR1, the second direction DR2, and the third direction DR3 may be an X-axis direction, a Y-axis direction, and a Z-axis direction, respectively.

In addition, in an embodiment, the upper driving unit 3310 may rotate the substrate chuck 3300 around the Z-axis to adjust the azimuthal angle of the backplane substrate 3002. In addition, in order to adjust the inclination of the backplane substrate 3002, the upper driving unit 3310 may rotate the substrate chuck 3300 around the X-axis and, also, may rotate the substrate chuck 3300 around the Y-axis. For example, the upper driving unit 3310 may include a hexapod actuator that provides a motion of 6 degrees of freedom (X, Y, Z, θx, θy, and θz).

In an embodiment, a mask stage 3400 on which the deposition mask 2000 is placed may be disposed above the deposition source 3200. That is, the mask stage 3400 may be disposed under the substrate chuck 3300 and may support an edge portion of the deposition mask 2000. The deposition mask 2000 may be carried into the process chamber 3100 by the transfer robot. For example, the deposition mask 2000 brought into the process chamber 3100 by the transfer robot may be placed on the lift fingers, and the lift fingers may be lowered to load the deposition mask 2000 on the mask stage 3400.

In an embodiment, the mask stage 3400 may include a mask chuck 3410 for supporting the deposition mask 2000. Although not shown in detail, the mask chuck 3410 may have a circular ring shape to support the edge portion of the deposition mask 2000. For example, the mask chuck 3410 may be an electrostatic chuck configured to hold the edge portion of the deposition mask 2000 using an electrostatic force.

In an embodiment, the mask stage 3400 may include a support plate 3420 for supporting the mask chuck 3410. The support plate 3420 may have an opening to allow the mask cell regions 2210 of the deposition mask 2000 to be exposed toward the deposition source 3200, and a lower driving unit 3430 for adjusting the position and angle of the deposition mask 2000 may be disposed between the support plate 3420 and the mask chuck 3410.

For example, in an embodiment, the lower driving unit 3430 may move the mask chuck 3410 in the directions DR1 and DR2 to adjust the horizontal position of the deposition mask 2000, and may rotate the mask chuck 3410 around the Z-axis to adjust the azimuthal angle of the deposition mask 2000. As an example, the lower driving unit 3430 may include a piezo actuator that provides a motion of 3 degrees of freedom (X, Y, and θz), and the piezo actuator may have a quadrilateral ring shape.

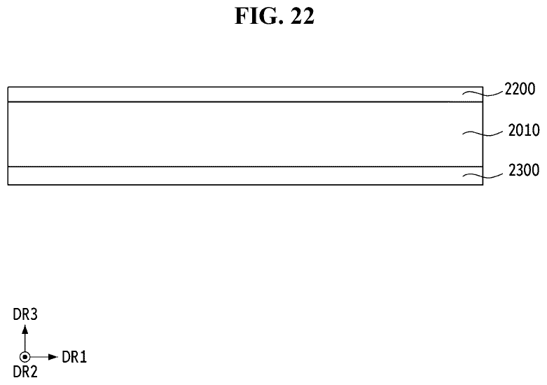

FIGS. 22 to 29 are schematic cross-sectional views illustrating a method of manufacturing a deposition mask, according to still another embodiment.

In an embodiment and referring to FIG. 22, the membrane 2200 may be formed on a mask substrate 2010. For example, a single crystal silicon substrate may be used as the mask substrate 2010, and the mask substrate 2010 may function as the mask frame 2100 of the deposition mask 2000. The membrane 2200 may be made of silicon nitride (SiNx) and may be formed to have a thickness of about 0.5 μm to about 3 μm on the mask substrate 2010 through a TCVD process. The membrane 2200 may be formed by a reaction between a first source gas containing silicon and a second source gas containing nitrogen. By way of non-limiting example, dichlorosilane (DCS) (SiH₂Cl₂) gas may be used as the first source gas, and ammonia (NH₃) gas may be used as the second source gas.

In an embodiment, the membrane 2200 may be formed on the front surface of the mask substrate 2010, and the rear inorganic film 2300 may be formed on the rear surface of the mask substrate 2010. For example, the rear inorganic film 2300 may be formed simultaneously with the membrane 2200. That is, the rear inorganic film 2300 may be formed to have the same thickness as the membrane 2200 through a TCVD process.

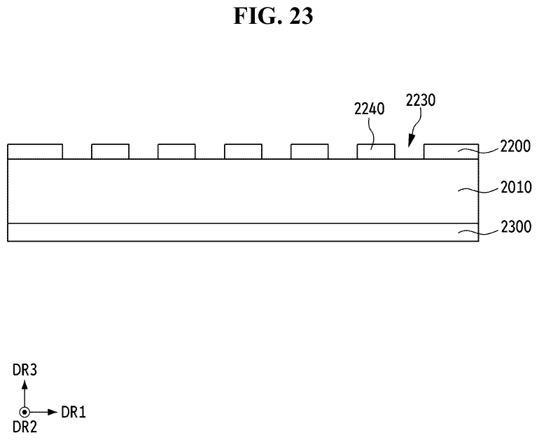

In an embodiment and referring to FIG. 23, the membrane 2200 may be patterned to form the plurality of pixel openings 2230 that expose the mask substrate 2010. For example, after forming on the membrane 2200 a first photoresist pattern (not shown) exposing the portions where the pixel openings 2230 are to be formed, an etching process using the first photoresist pattern as an etching mask may be performed to form the pixel openings 2230 that expose the mask substrate 2010.

For example, in an embodiment, the pixel openings 2230 may be formed through a reactive ion etching (RIE) process using a reactive gas such as CHF₃, CH₃F, CH₂F₂, CHF₆, CF₄, C₂F₆, or C₃F₆ and a sputtering gas such as Ar or O₂/Ar. In this case, an inductively coupled plasma (ICP) source or a capacitively coupled plasma (CCP) source may be used as a plasma source. In particular, by appropriately controlling flow rates of the reactive gas and the sputtering gas, an internal temperature of a process chamber, RF power for plasma formation, bias power applied to a chuck on which the mask substrate 2010 is placed, and the like, the pixel openings 2230 may be made to have a constant width in a thickness direction of the membrane 2200. The first photoresist pattern may be removed through a stripping and/or ashing process after the pixel openings 2230 are formed.

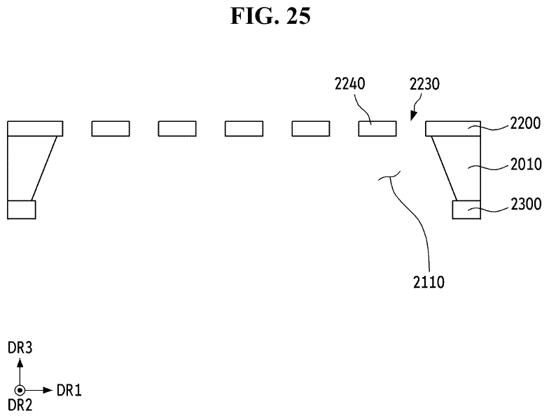

In an embodiment and referring to FIGS. 24 and 25, the mask substrate 2010 may be patterned to form the cell openings 2110 that expose the membrane 2200. For example, after forming on the rear inorganic film 2300 a second photoresist pattern (not shown) exposing the portions where the cell openings 2110 are to be formed, an anisotropic etching process, such as an RIE process, may be performed using the second photoresist pattern as an etching mask. The anisotropic etching process may be performed until rear portions of the mask substrate 2010, i.e., the portions where the cell openings 2110 are to be formed, are exposed, and, as a result, the rear openings 2310 exposing the rear portions of the mask substrate 2010 may be formed, as shown in FIG. 24. The second photoresist pattern may be removed through a stripping and/or ashing process after the rear openings 2310 are formed.

In an embodiment and referring to FIG. 25, the mask substrate 2010 may be partially removed to expose the membrane 2200 through a wet etching process using the rear inorganic film 2300 as an etching mask, thereby forming the plurality of cell openings 2110. For example, the wet etching process may be performed using an etching solution containing TMAH or potassium hydroxide (KOH). In this case, the <100> crystal direction of the single crystal silicon substrate used as the mask substrate 2010 may be the third direction DR3, and accordingly, the cell openings 2110 may be formed to have a width that gradually decreases from the rear surface of the mask substrate 2010 toward the membrane 2200, i.e., in the third direction DR3, by the wet etching process. For example, each of the inner surfaces of the cell openings 2110 may be formed to have an inclination of about 54.74°.

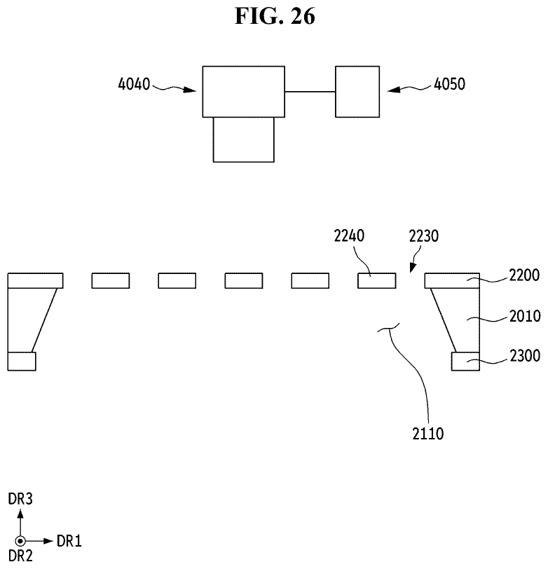

In an embodiment and referring to FIG. 26, after the cell openings 2110 are formed, the gap between the pixel openings 2230 and the PPA of the pixel openings 2230 may be measured using an inspection camera 4040. For example, a line scan camera may be used as the inspection camera 4040, and the gap between the pixel openings 2230 and the PPA of the pixel openings 2230 may be measured from image information acquired by the inspection camera 4040.

For example, in an embodiment, the image information may be transmitted to an image analysis device 4050, and the image analysis device 4050 may measure the gap between the pixel openings 2230 and the PPA of the pixel openings 2230 from the image information. In addition, the image analysis device 4050 may detect at least one first portion 2242 where the gap between the pixel openings 2230 is wider than the predetermined gap and/or at least one second portion 2244 where the gap between the pixel openings 2230 is narrower than the predetermined gap.

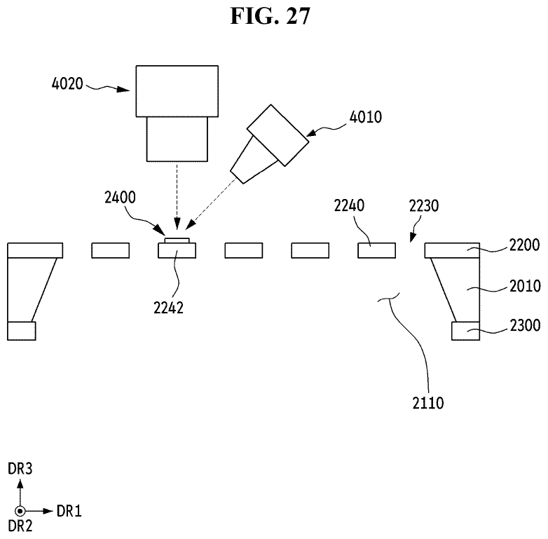

In an embodiment and referring to FIG. 27, when the first portion 2242 where the gap between the pixel openings 2230 is wider than the predetermined gap is detected, the heterogeneous material pattern 2400 may be formed on the first portion 2242. In particular, in order to reduce the width of the first portion 2242, the heterogeneous material pattern 2400 may be made of a material having a higher coefficient of thermal expansion than the membrane 2200 and may extend in a direction (see FIG. 16) that is perpendicular to a direction of the gap between the pixel openings 2230 located on both sides of the first portion 2242.

For example, in an embodiment, the heterogeneous material pattern 2400 may include metal, and may be formed on the first portion 2242 to have a thickness of about 0.1 μm to about 2 μm and a width of about 0.1 μm to about 3 μm. By way of non-limiting example, the heterogeneous material pattern 2400 may include tungsten (W), molybdenum (Mo), zirconium (Zr), hafnium (Hf), chromium (Cr), tantalum (Ta), titanium (Ti), platinum (Pt), yttrium (Y), palladium (Pd), nickel (Ni), cobalt (Co), gold (Au), copper (Cu), silver (Ag), tin (Sn), aluminum (Al), or zinc (Zn). Also, the heterogeneous material pattern 2400 may include an oxide or nitride of the aforementioned metal.

In an embodiment, the heterogeneous material pattern 2400 may be formed through an LCVD process. To elaborate, a precursor gas containing the metal may be provided onto the first portion 2242 through the nozzle 4010, and a laser beam may be irradiated onto the first portion 2242 from the laser device 4020. For example, a CO₂ laser or an Nd:YAG laser may be used in the LCVD process, and the first portion 2242 may be locally heated by the laser beam. In addition, the precursor gas may be decomposed by the irradiation of the laser beam, and a metal component of the precursor gas may be deposited on the first portion 2242.

In particular, as shown in FIGS. 16 and 17, while the heterogeneous material pattern 2400 and the first portion 2242 are being cooled after the heterogeneous material pattern 2400 is formed on the first portion 2242 as described above, the width d1 of the first portion 2242 may be reduced due to a difference in the coefficient of thermal expansion between the heterogeneous material pattern 2400 and the membrane 2200, and, accordingly, the width d1 of the first portion 2242 may be corrected to the gap d2 which is the same as the normal gap d between the pixel openings 2230.

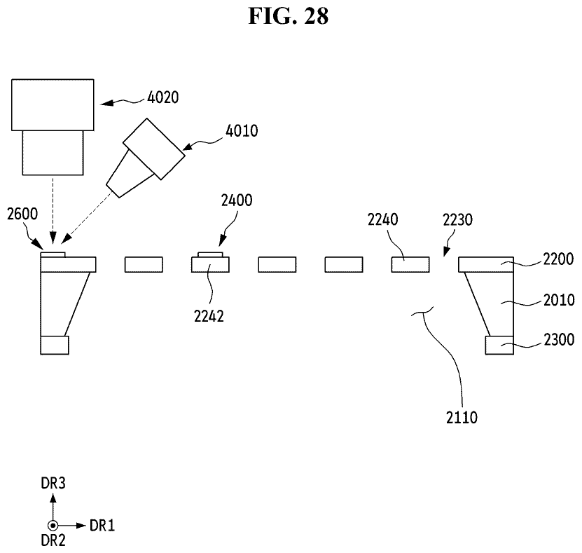

In an embodiment and referring to FIG. 28, the spacers 2600 may be formed on the membrane 2200. For example, the spacers 2600 may be formed on the grid region 2220 and the edge region 2222 of the membrane 2200 through an LCVD process, as illustrated in FIG. 13. In particular, the spacers 2600 may be formed to have the same thickness as the heterogeneous material pattern 2400 to make the gap between the backplane substrate 3002 and the deposition mask 2000 uniform during the deposition process.

The spacers 2600 are desirably formed of the same material as the membrane 2200 to prevent deformation of the membrane 2200. As another example, the spacers 2600 may be formed of the same material as the heterogeneous material pattern 2400. As still another example, the spacers 2600 may be formed of a material having a coefficient of thermal expansion similar to that of the membrane 2200 to reduce deformation of the membrane 2200. By way of non-limiting example, when the membrane 2200 is made of silicon nitride (SiNx), the spacers 2600 may be made of a material such as silicon (Si), aluminum nitride (AlN), tungsten (W), molybdenum (Mo), or the like, which has a coefficient of thermal expansion similar to that of the silicon nitride (SiNx).

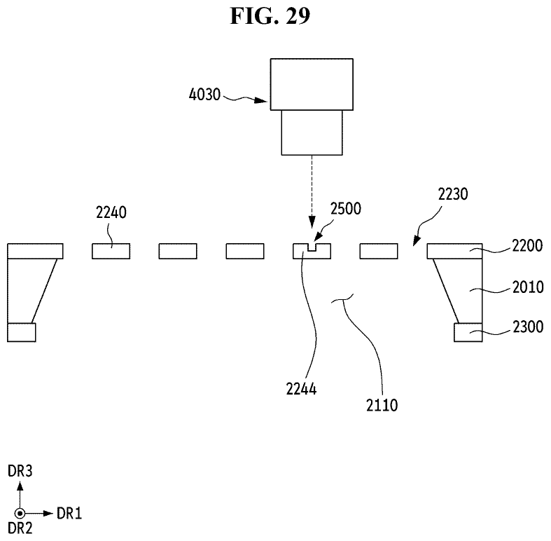

In an embodiment and referring to FIG. 29, when the second portion 2244 where the gap between the pixel openings 2230 is narrower than the predetermined gap is detected, the groove 2500 may be formed in the second portion 2244 to correct the width of the second portion 2244. In particular, the groove 2500 may extend in a direction (see FIG. 19) that is perpendicular to the direction of the gap between the neighboring pixel openings 2300 to increase the gap between the neighboring pixel openings 2300, that is, the width of the second portion 2244.

For example, the groove 2500 may be formed through an LA process. Specifically, a laser beam may be irradiated onto the second portion 2244 from a laser device 4030, and the second portion 2244 may be partially removed by the irradiation of the laser beam, thereby forming the groove 2500.

In an embodiment, in the LA process, an ultrashort pulse laser such as a picosecond laser or a femtosecond laser may be used, and the groove 2500 may be formed to have a width of about 0.1 μm to about 2 μm and a depth of about 0.1 μm to about 2 μm. In particular, when the depth of the groove 2500 is less than about 0.1 times the thickness of the membrane 2200, the width of the second portion 2244 may not be sufficiently expanded, and when the depth of the groove 2500 is greater than about 0.7 times the thickness of the membrane 2200, a new opening may be formed through the second portion 2244. Thus, it is desirable that the groove 2500 is formed to have a depth of about 0.1 to about 0.7 times the thickness of the membrane 2200.

In an embodiment, after the groove 2500 is formed by the LA process, the width d1 of the second portion 2244 may be increased due to the residual stress of the membrane 2200, and, accordingly, the width d1 of the second portion 2244 may be corrected to the gap d2 which is the same as the normal gap d between the pixel openings 2230, as shown in FIGS. 19 and 20.

As another example, in an embodiment, as shown in FIG. 21, when both the first portion 2242 and the second portion 2244 are detected, the heterogeneous material pattern 2400 may be formed on the first portion 2242, and the groove 2500 may be formed in the second portion 2244.

According to embodiments of the invention as described above, when the portions 2242 and 2244 in which the gap between the pixel openings 2230 falls outside of the predetermined tolerance range are detected, the gap between the pixel openings 2230 may be corrected using the heterogeneous material pattern 2400 and the groove 2500, so that the gap between the pixel openings 2230 may be made uniform, and the PPA of the pixel openings 2230 may be significantly improved.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made to the invention without departing from the spirit or scope of the invention.

What is claimed is:

1. A deposition mask comprising:
a mask frame having a cell opening; and
a membrane disposed on the mask frame and having a plurality of pixel openings connected to the cell opening,
wherein the membrane comprises a rib region defining the plurality of pixel openings, and
at least one heterogeneous material pattern made of a material that is different from the membrane is disposed on the rib region or at least one groove is formed in the rib region.

2. The deposition mask of claim 1, wherein the heterogeneous material pattern extends in a direction that is perpendicular to a direction of a gap between neighboring pixel openings.

3. The deposition mask of claim 1, wherein the heterogeneous material pattern has a higher coefficient of thermal expansion than the membrane.

4. The deposition mask of claim 1, wherein the heterogeneous material pattern comprises metal.

5. The deposition mask of claim 4, wherein the heterogeneous material pattern comprises tungsten (W), molybdenum (Mo), zirconium (Zr), hafnium (Hf), chromium (Cr), tantalum (Ta), titanium (Ti), platinum (Pt), yttrium (Y), palladium (Pd), nickel (Ni), cobalt (Co), gold (Au), copper (Cu), silver (Ag), tin (Sn), aluminum (Al), or zinc (Zn).

6. The deposition mask of claim 1, wherein the groove extends in a direction perpendicular to a direction of a gap between neighboring pixel openings.

7. The deposition mask of claim 1, wherein the groove has a depth of about 0.1 to about 0.7 times a thickness of the membrane.

8. The deposition mask of claim 1, further comprising at least one spacer disposed on the membrane and having the same thickness as the heterogeneous material pattern.

9. The deposition mask of claim 8, wherein the spacer is made of the same material as the membrane or the heterogeneous material pattern.

10. A method of manufacturing a deposition mask, comprising:
forming a membrane on a substrate;
patterning the membrane to form a plurality of pixel openings exposing the substrate;
patterning the substrate to form a cell opening connected to the plurality of pixel openings;
measuring a gap between the plurality of pixel openings;
detecting a first portion where the gap between the plurality of pixel openings is wider than a predetermined gap, or a second portion where the gap between the plurality of pixel openings is narrower than the predetermined gap;
forming at least one heterogeneous material pattern made of a material different from the membrane on the first portion when the first portion is detected; and
forming at least one groove in the second portion when the second portion is detected.

11. The method of claim 10, wherein the heterogeneous material pattern extends in a direction that is perpendicular to a direction of a gap between pixel openings disposed on both sides of the first portion.

12. The method of claim 10, wherein the heterogeneous material pattern has a higher coefficient of thermal expansion than the membrane.

13. The method of claim 10, wherein the heterogeneous material pattern comprises metal.

14. The method of claim 13, wherein the heterogeneous material pattern comprises tungsten (W), molybdenum (Mo), zirconium (Zr), hafnium (Hf), chromium (Cr), tantalum (Ta), titanium (Ti), platinum (Pt), yttrium (Y), palladium (Pd), nickel (Ni), cobalt (Co), gold (Au), copper (Cu), silver (Ag), tin (Sn), aluminum (Al), or zinc (Zn).

15. The method of claim 13, wherein the heterogeneous material pattern is formed through a laser chemical vapor deposition process.

16. The method of claim 13, wherein the forming of the heterogeneous material pattern comprises:
providing a source gas comprising the metal onto the first portion; and
irradiating a laser beam onto the first portion to form the heterogeneous material pattern.

17. The method of claim 10, wherein the groove extends in a direction that is perpendicular to a direction of a gap between pixel openings disposed on both sides of the second portion.

18. The method of claim 10, wherein the groove has a depth of about 0.1 to about 0.7 times a thickness of the membrane, and is formed through a laser ablation process.

19. The method of claim 10, further comprising forming at least one spacer on the membrane,
wherein the spacer has the same thickness as the heterogeneous material pattern, and is made of the same material as the membrane or the heterogeneous material pattern.

20. An electronic device comprising a display panel,
wherein the display panel comprises a backplane substrate and light-emitting layers formed on the backplane substrate by using a deposition mask,
wherein the deposition mask comprises:
a mask frame having a cell opening; and
a membrane disposed on the mask frame and having a plurality of pixel openings connected to the cell opening, and
wherein the membrane comprises a rib region defining the plurality of pixel openings, and
at least one heterogeneous material pattern made of a material that is different from the membrane is disposed on the rib region or at least one groove is formed in the rib region.
